(19) United States
(12) Patent Application Publication
(10) Pub. No.: US 2025/0226368 A1
(43) Pub. Date: Jul. 10, 2025

(54) CLEANER, DISPLAY PANEL MANUFACTURED USING THE SAME, AND METHOD OF MANUFACTURING THE SAME

(71) Applicant: Samsung Display Co., LTD., Yongin-si (KR)

(72) Inventor: Jong Hyup KIM, Yongin-si (KR)

(73) Assignee: Samsung Display Co., LTD., Yongin-si (KR)

(21) Appl. No.: 18/920,110

(22) Filed: Oct. 18, 2024

(30) Foreign Application Priority Data
Jan. 5, 2024 (KR) 10-2024-0002030

(51) Int. Cl. H01L 25/16; H01L 33/00

(52) U.S. Cl. CPC H01L 25/167; H10H 20/01

(57) ABSTRACT

A cleaner includes a body portion including a groove recessed toward inside of the body portion, a first inclined portion extending from the body portion, connected to the groove, and forming a first inclined angle that is an obtuse angle with a ground, and a second inclined portion connected to the first inclined portion and forming a second inclined angle with the ground, the second inclined angle being smaller than the first inclined angle. The cleaner planarizes an upper surface of a conductive material used in a bonding process.

### CROSS-REFERENCE TO RELATED APPLICATION(S)

The application claims priority to and the benefits of Korean Patent Application No. 10-2024-0002030 under 35 U.S.C. 119, filed on Jan. 5, 2024, in the Korean Intellectual Property Office (KIPO), the entire contents of which are incorporated herein by reference.

### BACKGROUND

### 1. Technical Field

Embodiments of the disclosure relate to a cleaner, a display panel manufactured using the same, and a method of manufacturing the same.

### 2. Description of the Related Art

As information technology develops, the importance of a display device as a connection medium between a user and information is being emphasized. In response to this, the use of display devices such as a liquid crystal display device and an organic light emitting display device is increasing.

For example, a display panel can be formed by transferring a light emitting element onto a substrate on which a thin film transistor is formed. A display device including the display panel formed in this way may be used.

In a process of manufacturing the display panel as described above, a process of bonding the light emitting element using a conductive material may be performed to reduce electrical resistance in an area where the thin film transistor and the light emitting element are connected to each other.

### SUMMARY

Embodiments provide a cleaner capable of planarizing an upper surface of a conductive material used in a bonding process, a display panel manufactured using the same, and a method of manufacturing the same.

According to an embodiment of the disclosure, a cleaner may include a body portion including a groove recessed toward inside of the body portion, a first inclined portion extending from the body portion, connected to the groove, and forming a first inclined angle that is an obtuse angle with a ground, and a second inclined portion connected to the first inclined portion and forming a second inclined angle with the ground, the second inclined angle being smaller than the first inclined angle.

An elastic modulus of the first inclined portion may be smaller than an elastic modulus of the second inclined portion.

The first inclined portion may be composed of one of rubber and silicone, and the second inclined portion may be composed of one of rubber and silicone. An elastic modulus of a material constituting the first inclined portion may be smaller than an elastic modulus of a material constituting the second inclined portion.

The first inclined portion may include a wedge shape forming the first inclined angle with the ground, and the second inclined portion may include a wedge shape forming the second inclined angle with the ground.

The body portion may further include a sub-groove further recessed to extend in a horizontal direction from the groove, and the second inclined portion may be located in the horizontal direction from the first inclined portion.

A distance between the first inclined portion and the ground may be equal to a distance between the second inclined portion and the ground.

A distance between the first inclined portion and the ground may be greater than a distance between the second inclined portion and the ground.

According to an embodiment of the disclosure, a display panel may include a thin film transistor layer located on a substrate and in which a pixel circuit including at least one transistor is disposed, a pixel electrode located on the thin film transistor layer and connected to the pixel circuit, a common electrode located on the thin film transistor layer and to which a first power source voltage is applied, a bank located on at least a portion of the common electrode and at least a portion of the pixel electrode, a conductive material located on the common electrode and the pixel electrode in an area surrounded by the bank, and a light emitting element connected to the common electrode and the pixel electrode in the area surrounded by the bank with the conductive material interposed between the light emitting element and the common electrode and between the light emitting element and the pixel electrode. The conductive material on the bank may be removed by a first inclined portion of a cleaner and planarized by a second inclined portion of the cleaner.

A first residue of the conductive material removed by the first inclined portion may be accommodated in a groove of the cleaner, and the groove of the cleaner may be connected to the first inclined portion of the cleaner.

A second residue corresponding to an upper surface of the conductive material from which the first residue has been removed may be planarized by the second inclined portion.

The bank may have a tapered shape in a cross-sectional view.

The bank may have an inverted tapered shape in a cross-sectional view.

According to an embodiment of the disclosure, a method of manufacturing a display panel may include providing plasma onto a common electrode and a pixel electrode located in an area surrounded by a bank on a substrate by a plasma providing device; providing a conductive material on the common electrode, the pixel electrode, and the bank by a conductive material providing device; removing and accommodating the conductive material on the bank by a cleaner, and planarizing an upper surface of the conductive material by the cleaner; and evaporating at least a portion of the conductive material in the area surrounded by the bank by a heater.

In the providing of the plasma onto the common electrode and the pixel electrode located in the area surrounded by the bank on the substrate by the plasma providing device, a mask for blocking the plasma may be positioned on the bank, and an opening of the mask may be positioned corresponding to the area surrounded by the bank.

The removing and accommodating of the conductive material on the bank by the cleaner, and the planarizing of the upper surface of the conductive material by the cleaner may include shaving and removing the conductive material by a first inclined portion of the cleaner, accommodating a first residue corresponding to the conductive material shaved by the first inclined portion in a groove of the cleaner, and planarizing the upper surface of the conductive material from which the first residue has been removed by a second inclined portion of the cleaner.

The second inclined portion may be located in a horizontal direction from the first inclined portion, and in the accommodating of the first residue corresponding to the conductive material shaved by the first inclined portion in the groove of the cleaner, the first residue may be further accommodated in a sub-groove extending in the horizontal direction from the groove.

A first inclined angle formed by the first inclined portion with a ground may be an obtuse angle. The first inclined angle may be greater than a second inclined angle formed by the second inclined portion with the ground.

A distance between the first inclined portion and the ground may be equal to a distance between the second inclined portion and the ground.

In the evaporating of the at least a portion of the conductive material in the area surrounded by the bank by the heater, the bank may have a tapered shape in a cross-sectional view.

In the evaporating of the at least a portion of the conductive material in the area surrounded by the bank by the heater, the bank may have an inverted tapered shape in a cross-sectional view.

### BRIEF DESCRIPTION OF THE DRAWINGS

The accompanying drawings, which are included to provide a further understanding of the disclosure, and are incorporated in and constitute a part of this specification, illustrate embodiments of the disclosure, and, together with the description, serve to explain principles of the disclosure.

FIG. 1 is a plan view illustrating a display device according to embodiments of the disclosure.

FIG. 2 is a schematic diagram illustrating an embodiment of a pixel of FIG. 1.

FIG. 3 is a schematic diagram illustrating another embodiment of the pixel of FIG. 1.

FIG. 4 is a schematic cross-sectional view illustrating an embodiment of the display device taken along line A-A′ in FIG. 3.

FIG. 5 is a plan view illustrating a tiled display device including multiple display devices according to embodiments of the disclosure.

FIG. 6 is an enlarged plan view illustrating area AR1 of FIG. 5.

FIG. 7 is a schematic cross-sectional view illustrating an embodiment of the tiled display device taken along line B-B′ in FIG. 6.

FIG. 8 is an enlarged plan view illustrating area AR2 of FIG. 5.

FIG. 9 is a schematic cross-sectional view illustrating an embodiment of the tiled display device taken along line F-F′ in FIG. 8.

FIG. 10 is a block diagram illustrating the tiled display device according to embodiments of the disclosure.

FIG. 11 is a schematic cross-sectional view illustrating a process of transferring a light emitting element.

FIG. 12 is a schematic cross-sectional view illustrating an embodiment of a backplane substrate onto which the light emitting element is transferred.

FIG. 13 is a schematic cross-sectional view illustrating an embodiment of a step of providing plasma onto a common electrode and a pixel electrode.

FIG. 14 is a schematic cross-sectional view illustrating an embodiment of a step of providing a conductive material on the common electrode and the pixel electrode.

FIG. 15 is a schematic cross-sectional view illustrating an embodiment of a step of removing the conductive material using a cleaner.

FIG. 16 is a schematic cross-sectional view illustrating an embodiment in a state in which the conductive material is removed by the cleaner.

FIG. 17 is a schematic cross-sectional view illustrating an embodiment of a step of removing the conductive material using a heater.

FIG. 18 is a schematic cross-sectional view of a cleaner according to an embodiment.

FIG. 19 is a schematic cross-sectional view of a cleaner according to another embodiment.

FIG. 20 is a schematic cross-sectional view illustrating angles formed by a first inclined portion and a second inclined portion with the ground in the cleaner according to embodiments of the disclosure.

FIG. 21A is a schematic cross-sectional view illustrating a distance between the first inclined portion and the second inclined portion and the ground according to embodiments of the disclosure.

FIG. 21B is a schematic cross-sectional view illustrating a distance between the first inclined portion and the second inclined portion and the ground according to embodiments of the disclosure.

FIG. 22 is a schematic cross-sectional view illustrating another embodiment of the step of providing the plasma onto the common electrode and the pixel electrode.

FIG. 23 is a schematic cross-sectional view illustrating another embodiment of the step of providing the conductive material on the common electrode and the pixel electrode.

FIG. 24 is a schematic cross-sectional view illustrating another embodiment of the step of removing the conductive material using the cleaner.

FIG. 25 is a schematic cross-sectional view illustrating another embodiment in the state in which the conductive material is removed by the cleaner.

FIG. 26 is a schematic cross-sectional view illustrating another embodiment of the step of removing the conductive material using the heater.

### DETAILED DESCRIPTION OF THE EMBODIMENTS

Hereinafter, various embodiments of the disclosure will be described in detail with reference to the accompanying drawings so that those of ordinary skill in the art may readily implement the disclosure. The disclosure may be embodied in various different forms and is not limited to the embodiments described herein.

In order to clearly describe the disclosure, parts that are not related to the description are omitted, and the same or similar components are denoted by the same reference numerals throughout the specification. Therefore, the reference numerals described above may also be used in other drawings.

In addition, the size and thickness of each component shown in the drawings are arbitrarily shown for convenience of description, and thus the disclosure is not necessarily limited to those shown in the drawings. In the drawings, thicknesses may be exaggerated to clearly express the layers and regions.

In the description, the expression “is the same” may mean “substantially the same”. That is, it may be the same enough to convince those of ordinary skill in the art to be the same. In other expressions, “substantially” may be omitted.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element. In the disclosure, the singular expressions are intended to include the plural expressions as well, unless the context clearly indicates otherwise.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the attached drawings.

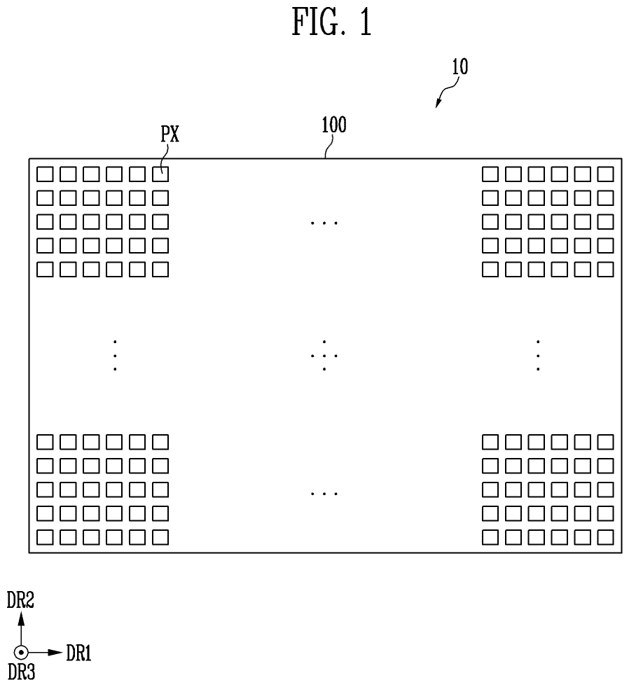

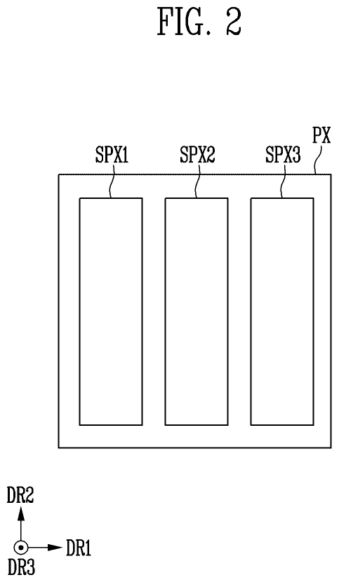

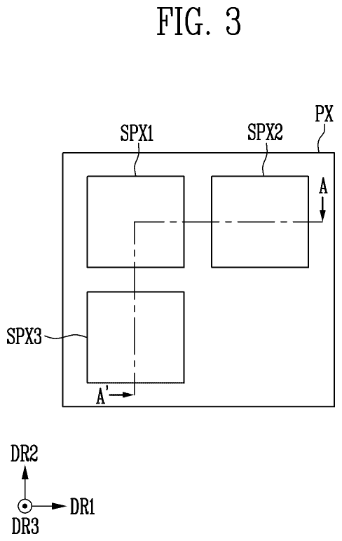

FIG. 1 is a plan view illustrating a display device 10 according to embodiments of the disclosure. FIG. 2 is a schematic diagram illustrating an embodiment of a pixel PX of FIG. 1. FIG. 3 is a schematic diagram illustrating another embodiment of the pixel PX of FIG. 1.

Referring to FIG. 1, the display device 10 may be a device that displays a moving image or a still image. The display device 10 may be used as display screens for various products such as television, a laptop, a monitor, a billboard, and an Internet of Things (IoT) as well as portable electronic devices such as a mobile phone, a smart phone, a tablet personal computer, a smart watch, a watch phone, a mobile communication terminal, an electronic notebook, an e-book, a portable multimedia player (PMP), a navigation, and an UMPC (Ultra Mobile PC).

A display panel 100 may be formed in the form of a rectangular flat plate having a long side in a first direction DR1 and a short side in a second direction DR2 that intersects the first direction DR1. A corner portion where the long side in the first direction DR1 and the short side in the second direction DR2 meet may be rounded to have a curvature or may be formed at a right angle. The shape of the display panel 100 in a plan view is not limited to a rectangular shape, but may be formed in another polygonal, circular, or oval shapes. The display panel 100 may be formed flat, but the disclosure is not limited thereto. For example, the display panel 100 may include curved portions formed at left and right ends and having a constant curvature or a changing curvature. In another embodiment, the display panel 100 may be flexible so that it can be curved, bent, folded, or rolled.

The display panel 100 may include pixels PX for displaying an image, scan lines extending in the first direction DR1, and data lines extending in the second direction DR2. The pixels PX may be arranged in a matrix form in the first direction DR1 and the second direction DR2. The first direction DR1 and the second direction DR2 may be orthogonal to each other (for example, horizontal x-axis and vertical y-axis), but the disclosure is not limited thereto.

A pixel PX may include multiple sub-pixels SPX1, SPX2, and SPX3, as shown in FIGS. 2 and 3. FIGS. 2 and 3 show an embodiment in which the pixel PX includes three sub-pixels SPX1, SPX2, and SPX3, for example, a first sub-pixel SPX1, a second sub-pixel SPX2, and a third sub-pixel SPX3, but the disclosure is not limited thereto.

Each of the first sub-pixel SPX1, the second sub-pixel SPX2, and the third sub-pixel SPX3 may be electrically connected to one of multiple data lines and may be electrically connected to at least one of multiple scan lines.

Each of the first sub-pixel SPX1, the second sub-pixel SPX2, and the third sub-pixel SPX3 may have a rectangular, square, or diamond shape in a plan view. For example, each of the first sub-pixel SPX1, the second sub-pixel SPX2, and the third sub-pixel SPX3 may have a rectangular shape having a short side in the first direction DR1 and a long side in the second direction DR2 in a plan view as shown in FIG. 2. In another embodiment, each of the first sub-pixel SPX1, the second sub-pixel SPX2, and the third sub-pixel SPX3 may have a square or diamond shape in a plan view including sides having a same length in the first direction DR1 and the second direction DR2 as shown in FIG. 3.

As shown in FIG. 2, the first sub-pixel SPX1, the second sub-pixel SPX2, and the third sub-pixel SPX3 may be arranged in the first direction DR1.

In another embodiment, one of the second sub-pixel SPX2 and the third sub-pixel SPX3 and the first sub-pixel SPX1 may be arranged in the first direction DR1, and another one of the second sub-pixel SPX2 and the third sub-pixel SPX3 and the first sub-pixel SPX1 may be arranged in the second direction DR2. For example, as shown in FIG. 3, the first sub-pixel SPX1 and the second sub-pixel SPX2 may be arranged in the first direction DR1, and the first sub-pixel SPX1 and the third sub-pixel SPX3 may be arranged in the second direction DR2. In another embodiment, one of the first sub-pixel SPX1 and the third sub-pixel SPX3 and the second sub-pixel SPX2 may be arranged in the first direction DR1, and another one of the first sub-pixel SPX1 and the third sub-pixel SPX3 and the second sub-pixel SPX2 may be arranged in the second direction DR2. In another embodiment, one of the first sub-pixel SPX1 and the second sub-pixel SPX2 and the third sub-pixel SPX3 may be arranged in the first direction DR1, and another one of the first sub-pixel SPX1 and the second sub-pixel SPX2 and the third sub-pixel SPX3 may be arranged in the second direction DR2.

The first sub-pixel SPX1 may emit first light, the second sub-pixel SPX2 may emit second light, and the third sub-pixel SPX3 may emit third light. In an embodiment, the first light may be light in a red wavelength band, the second light may be light in a green wavelength band, and the third light may be light in a blue wavelength band. The red wavelength band may be a wavelength band in a range of approximately 600 nanometer (nm) to 750 nm, the green wavelength band may be a wavelength band in a range of approximately 480 nm to 560 nm, and the blue wavelength band may be a wavelength band in a range of approximately 370 nm to 460 nm, but the disclosure is not limited thereto.

Each of the first sub-pixel SPX1, the second sub-pixel SPX2, and the third sub-pixel SPX3 may be a light emitting element that emits light and may include an inorganic light emitting element having an inorganic semiconductor. For example, the inorganic light emitting element may be a flip chip type micro light emitting diode (hereinafter, referred to as a micro LED), but the disclosure is not limited thereto.

As shown in FIGS. 2 and 3, an area of the first sub-pixel SPX1, an area of the second sub-pixel SPX2, and an area of the third sub-pixel SPX3 may be substantially the same in a plan view, but the disclosure is not limited thereto. At least one of the area of the first sub-pixel SPX1, the area of the second sub-pixel SPX2, and the area of the third sub-pixel SPX3 may be different from another one. In another embodiment, two of the area of the first sub-pixel SPX1, the area of the second sub-pixel SPX2, and the area of the third sub-pixel SPX3 may be substantially the same, and the remaining one may be different from the two. In another embodiment, the area of the first sub-pixel SPX1, the area of the second sub-pixel SPX2, and the area of the third sub-pixel SPX3 may be different from each other.

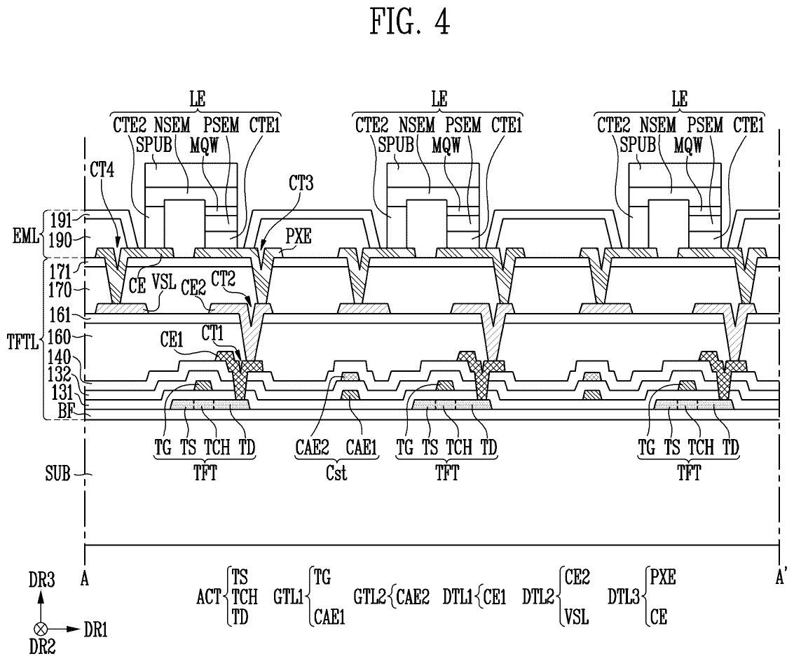

FIG. 4 is a schematic cross-sectional view illustrating an embodiment of the display device taken along line A-A′ in FIG. 3.

Referring to FIG. 4, a thin film transistor layer TFTL may be disposed on a substrate SUB. The thin film transistor layer TFTL may be a layer in which thin film transistors TFT are formed.

The thin film transistor layer TFTL may include an active layer ACT, a first gate layer GTL1, a second gate layer GTL2, a first data metal layer DTL1, and a second data metal layer DTL2. The thin film transistor layer TFTL may further include a buffer film BF, a first gate insulating film 131, a second gate insulating film 132, an interlayer insulating film 140, a first planarization film 160, a first insulating film 161, a second planarization film 170, and a second insulating film 171.

The substrate SUB may be a base substrate or a base member for supporting the display device 10 (see FIG. 1). The substrate SUB may be a rigid substrate made of glass. In another embodiment, the substrate SUB may be a flexible substrate capable of bending, folding, rolling, or the like, and the substrate SUB may include an insulating material such as a polymer resin including polyimide (PI).

The buffer film BF may be disposed on a surface of the substrate SUB. The buffer film BF may be a film to prevent penetration of air or moisture. The buffer film BF may be composed of multiple inorganic films stacked each other alternately. For example, the buffer film BF may be formed as a multi-layer in which one or more inorganic films selected from the group consisting of a silicon nitride layer, a silicon oxynitride layer, a silicon oxide layer, a titanium oxide layer, and an aluminum oxide layer are alternately stacked each other. The buffer film BF may be omitted.

The active layer ACT may be disposed on the buffer film BF. The active layer ACT may include a silicon semiconductor such as polycrystalline silicon, single crystalline silicon, low-temperature polycrystalline silicon, and amorphous silicon, or may include an oxide semiconductor.

The active layer ACT may include a channel TCH, a first electrode TS, and a second electrode TD of a thin film transistor TFT. The channel TCH of the thin film transistor TFT may be an area that overlaps a gate electrode TG of the thin film transistor TFT in the third direction DR3, which is a thickness direction of the substrate SUB. The first electrode TS of the thin film transistor TFT may be disposed on a side of the channel TCH, and the second electrode TD may be disposed on another side of the channel TCH. The first electrode TS and the second electrode TD of the thin film transistor TFT may be regions that do not overlap the gate electrode TG in the third direction DR3. The first electrode TS and the second electrode TD of the thin film transistor TFT may be a semiconductor (for example, a silicon semiconductor, an oxide semiconductor, or the like) doped with ions and may be conductive regions.

The first gate insulating film 131 may be disposed on the active layer ACT. For example, the first gate insulating film 131 may be an inorganic film and may be formed of at least one of, for example, a silicon nitride layer, a silicon oxynitride layer, a silicon oxide layer, a titanium oxide layer, and an aluminum oxide layer.

The first gate layer GTL1 may be disposed on the first gate insulating film 131. The first gate layer GTL1 may include the gate electrode TG of the thin film transistor TFT and a first capacitor electrode CAE1. The first gate layer GTL1 may be formed as a single layer or multiple layers made of at least one of molybdenum (Mo), aluminum (Al), chromium (Cr), gold (Au), titanium (Ti), nickel (Ni), neodymium (Nd), copper (Cu), and an alloy thereof.

The second gate insulating film 132 may be disposed on the first gate layer GTL1. For example, the second gate insulating film 132 may be an inorganic film and may be formed of at least one of, for example, a silicon nitride layer, a silicon oxynitride layer, a silicon oxide layer, a titanium oxide layer, and an aluminum oxide layer.

The second gate layer GTL2 may be disposed on the second gate insulating film 132. The second gate layer GTL2 may include a second capacitor electrode CAE2. The second gate layer GTL2 may be formed as a single layer or multiple layers made of at least one of molybdenum (Mo), aluminum (Al), chromium (Cr), gold (Au), titanium (Ti), nickel (Ni), neodymium (Nd), copper (Cu), and an alloy thereof.

The interlayer insulating film 140 may be disposed on the second gate layer GTL2. The interlayer insulating film 140 may be an inorganic film and may be formed of at least one of, for example, a silicon nitride layer, a silicon oxynitride layer, a silicon oxide layer, a titanium oxide layer, and an aluminum oxide layer.

The first data metal layer DTL1 including a first connection electrode CE1 may be disposed on the interlayer insulating film 140. The first data metal layer DTL1 may be formed as a single layer or multiple layers made of at least one of molybdenum (Mo), aluminum (Al), chromium (Cr), gold (Au), titanium (Ti), nickel (Ni), neodymium (Nd), copper (Cu), and an alloy thereof.

The first connection electrode CE1 may be connected (for example, electrically connected) to the first electrode TS or the second electrode TS of the thin film transistor TFT through a first contact hole CT1 penetrating the second gate insulating film 132 and the interlayer insulating film 140.

The first planarization film 160 may be formed on the first data metal layer DTL1 to planarize a step difference caused by the active layer ACT, the first gate layer GTL1, the second gate layer GTL2, and the first data metal layer DTL1. The first planarization film 160 may be formed of an organic film such as an acryl resin, an epoxy resin, a phenolic resin, a polyamide resin, and a polyimide resin.

The first insulating film 161 may be disposed on the first planarization film 160. The first insulating film 161 may be an inorganic film and may be formed of, for example, a silicon nitride layer, a silicon oxynitride layer, a silicon oxide layer, a titanium oxide layer, or an aluminum oxide layer.

The second data metal layer DTL2 may be formed on the first insulating film 161. The second data metal layer DTL2 may include a second connection electrode CE2 and a first power source line VSL. The second connection electrode CE2 may be connected to the first connection electrode CE1 through a second contact hole CT2 penetrating the first insulating film 161 and the first planarization film 160. The second data metal layer DTL2 may be formed as a single layer or multiple layers made of at least one of molybdenum (Mo), aluminum (Al), chromium (Cr), gold (Au), titanium (Ti), nickel (Ni), neodymium (Nd), copper (Cu), and an alloy thereof.

The second planarization film 170 may be formed on the second data metal layer DTL2 to planarize a step difference. The second planarization film 170 may be formed of an organic film such as an acryl resin, an epoxy resin, a phenolic resin, a polyamide resin, and a polyimide resin.

The second insulating film 171 may be disposed on the second planarization film 170. The second insulating film 171 may be an inorganic film and may be formed of, for example, a silicon nitride layer, a silicon oxynitride layer, a silicon oxide layer, a titanium oxide layer, or an aluminum oxide layer.

A light emitting element layer EML may be disposed on the second insulating film 171. The light emitting element layer EML may include a pixel electrode PXE, a common electrode CE, and a light emitting element LE. The third data metal layer DTL3 may include the pixel electrode PXE and the common electrode CE. Each of the first sub-pixel SPX1, the second sub-pixel SPX2, and the third sub-pixel SPX3 described above may include the light emitting element LE connected to the pixel electrode PXE and the common electrode CE. The pixel electrode PXE may be one (for example, an anode electrode) of an anode electrode or a cathode electrode of the light emitting element LE. The common electrode CE may be another one (for example, the cathode electrode) of the anode electrode and the cathode electrode of the light emitting element LE.

The pixel electrode PXE and the common electrode CE may be disposed on the second insulating film 171. The pixel electrode PXE may be connected (for example, electrically connected) to the second connection electrode CE2 through a third contact hole CT3 penetrating the second insulating film 171 and the second planarization film 170. The pixel electrode PXE may be electrically connected to the first electrode TS or the second electrode TD of the thin film transistor TFT through the first connection electrode CE1 and the second connection electrode CE2. Therefore, a pixel voltage or an anode voltage controlled by the thin film transistor TFT may be applied to the pixel electrode PXE.

The common electrode CE may be connected to the first power source line VSL through a fourth contact hole CT4 penetrating the second insulating film 171 and the second planarization film 170. A first power source voltage of the first power source line VSL may be applied to the common electrode CE.

The pixel electrode PXE and the common electrode CE may include a metal material having high reflectivity, such as a stacked structure of aluminum (Al) and titanium (Ti) (Ti/Al/Ti), a stacked structure of aluminum (Al) and indium tin oxide (ITO) (ITO/AI/ITO), APC (Ag—Pd—Cu) alloy, and a stacked structure of APC alloy and ITO (ITO/APC/ITO). The APC alloy may be an alloy of silver (Ag), palladium (Pd), and copper (Cu).

FIG. 4 schematically shows an embodiment that the light emitting element LE is a flip chip type micro LED in which a first contact electrode CTE1 and a second contact electrode CTE2 are arranged to face the pixel electrode PXE and the common electrode CE. The light emitting element LE may include an inorganic material such as gallium nitride (GaN). In the light emitting element LE, the length in the first direction DR1, the length in the second direction DR2, and the length in the third direction DR3 may be several micrometer (μm) to hundreds μm. For example, in the light emitting element LE, the length in the first direction DR1, the length in the second direction DR2, and the length in the third direction DR3 may be less than or equal to about 100 μm.

The light emitting element LE may be formed by growing on a semiconductor substrate such as a silicon wafer. The light emitting element LE may be transferred directly from the silicon wafer onto the pixel electrode PXE and the common electrode CE of the substrate SUB. In another embodiment, the light emitting element LE may be transferred onto the pixel electrode PXE and the common electrode CE of the substrate SUB using an electrostatic method using an electrostatic head or a stamping method using an elastic polymer material such as PDMS (polydimethylsiloxane) or silicon as a carrier substrate.

Referring to FIG. 4, each of the light emitting elements LE may have a light emitting structure including a base substrate SPUB, an n-type semiconductor NSEM, an active layer MQW, a p-type semiconductor PSEM, a first contact electrode CTE1, and a second contact electrode CTE2.

For example, the base substrate SPUB may be a sapphire substrate, but the disclosure is not limited thereto.

The n-type semiconductor NSEM may be disposed on a side of the base substrate SPUB. For example, the n-type semiconductor NSEM may be disposed on a lower surface (for example, in a direction opposite to the third direction DR3) of the base substrate SPUB. For example, the n-type semiconductor NSEM may be made of gallium nitride (GaN) doped with an n-type conductive dopant such as silicon (Si), germanium (Ge), selenium (Se), tellurium (Te), and tin (Sn).

The active layer MQW may be disposed on a portion of a side of the n-type semiconductor NSEM. The active layer MQW may include a material having a single or multi quantum well structure. In case that the active layer MQW includes a material having a multi quantum well structure, the active layer MQW may have a structure in which multiple well layers and multiple barrier layers are alternately stacked each other, the well layer may be formed of InGaN, and the barrier layer may be formed of GaN or AlGaN, but the disclosure is not limited thereto. In another embodiment, the active layer MQW may have a structure in which semiconductor materials having a high bandgap energy and semiconductor materials having a low bandgap energy are alternately stacked each other, and may include group 3 to 5 semiconductor materials depending on the wavelength band of the emitted light.

The p-type semiconductor PSEM may be disposed on a side (for example, a surface positioned in a direction opposite to the third direction DR3) of the active layer MQW. For example, the p-type semiconductor PSEM may be made of gallium nitride (GaN) doped with a p-type conductive dopant such as magnesium (Mg), zinc (Zn), calcium (Ca), and barium (Ba).

The first contact electrode CTE1 may be disposed on the p-type semiconductor PSEM (for example, in a direction opposite to the third direction DR3). The second contact electrode CTE2 may be disposed on another portion of a side of the n-type semiconductor NSEM (for example, in a direction opposite to the third direction DR3). Another portion of the side of the n-type semiconductor NSEM on which the second contact electrode CTE2 is disposed may be spaced apart from a portion of the side of the n-type semiconductor NSEM on which the active layer MQW is disposed.

The first contact electrode CTE1 and the pixel electrode PXE may be bonded to each other through a conductive adhesive member (not shown) such as an anisotropic conductive film (ACF) or anisotropic conductive paste (ACP). In another embodiment, the first contact electrode CTE1 and the pixel electrode PXE may be bonded to each other through a soldering process.

A bank 190 may be disposed on the second insulating film 171 and cover an edge of the pixel electrode PXE and an edge of the common electrode CE. The bank 190 may be formed of an organic film such as an acrylic resin, an epoxy resin, a phenolic resin, a polyamide resin, and a polyimide resin.

A bank insulating film 191 may be disposed on the bank 190. The bank insulating film 191 may cover the edge of the pixel electrode PXE and the edge of the common electrode CE. The bank insulating film 191 may be an inorganic film and may be formed of, for example, a silicon nitride layer, a silicon oxynitride layer, a silicon oxide layer, a titanium oxide layer, or an aluminum oxide layer.

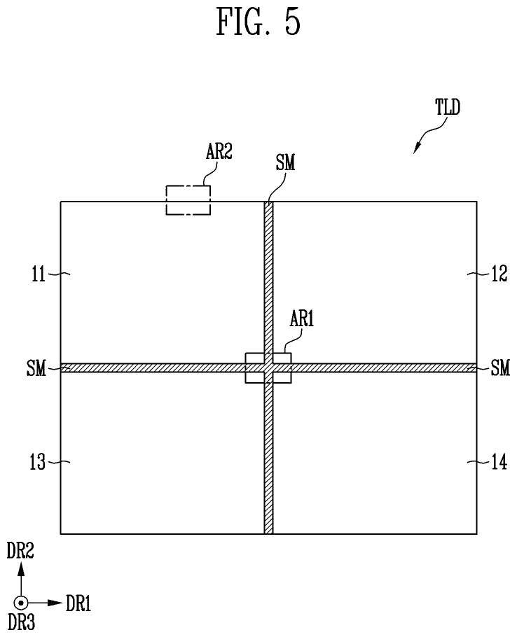

FIG. 5 is a plan view illustrating a tiled display device TLD including multiple display devices according to embodiments of the disclosure.

Referring to FIG. 5, the tiled display device TLD may include multiple display devices 11, 12, 13, and 14, and a seam SM. For example, the tiled display device TLD may include a first display device 11, a second display device 12, a third display device 13, and a fourth display device 14.

The display devices 11, 12, 13, and 14 may be arranged in a grid shape. The display devices 11, 12, 13, and 14 may be arranged in a matrix form with M (M may be an integer greater than 1) rows and N (N may be an integer greater than 1) columns. For example, the first display device 11 and the second display device 12 may be adjacent to each other in the first direction DR1. The first display device 11 and the third display device 13 may be adjacent to each other in the second direction DR2. The third display device 13 and the fourth display device 14 may be adjacent to each other in the first direction DR1. The second display device 12 and the fourth display device 14 may be adjacent to each other in the second direction DR2.

However, in the tiled display device TLD, the number and arrangement of the display devices 11, 12, 13, and 14 are not limited to those shown in FIG. 5. The number and arrangement of the display devices 11, 12, 13, and 14 included in the tiled display device TLD may be set depending on the size of the display devices 11, 12, 13, and 14 and the tiled display device TLD, the shape of the tiled display device TLD, and the like.

Referring to FIG. 5, the display devices 11, 12, 13, and 14 are shown as having the same size in a plan view, but the disclosure is not limited thereto. For example, one or more display devices among the display devices 11, 12, 13, and 14 may have a different size from the remaining display devices.

Each of the display devices 11, 12, 13, and 14 may have a rectangular shape including a long side and a short side in a plan view. The display devices 11, 12, 13, and 14 may be arranged so that long or short sides are connected to each other. Some or all of the display devices 11, 12, 13, and 14 may be disposed at an edge of the tiled display device TLD and may form a side of the tiled display device TLD. At least one display device among the display devices 11, 12, 13, and 14 may be disposed at least one corner of the tiled display device TLD and may form two adjacent sides of the tiled display device TLD. At least one display device among the display devices 11, 12, 13, and 14 may be surrounded by the remaining display devices.

Each of the display devices 11, 12, 13, and 14 and the display device 10 (see FIG. 1) described with reference to FIGS. 1 to 4 may be substantially the same. Therefore, description of each of the display devices 11, 12, 13, and 14 will be omitted.

The seam SM may include a coupling member or an adhesive member, and the display devices 11, 12, 13, and 14 may be connected to each other through the coupling member or the adhesive member of the seam SM. The seam SM may be disposed between the first display device 11 and the second display device 12, between the first display device 11 and the third display device 13, between the second display device 12 and the fourth display device 14, and between the third display device 13 and the fourth display device 14.

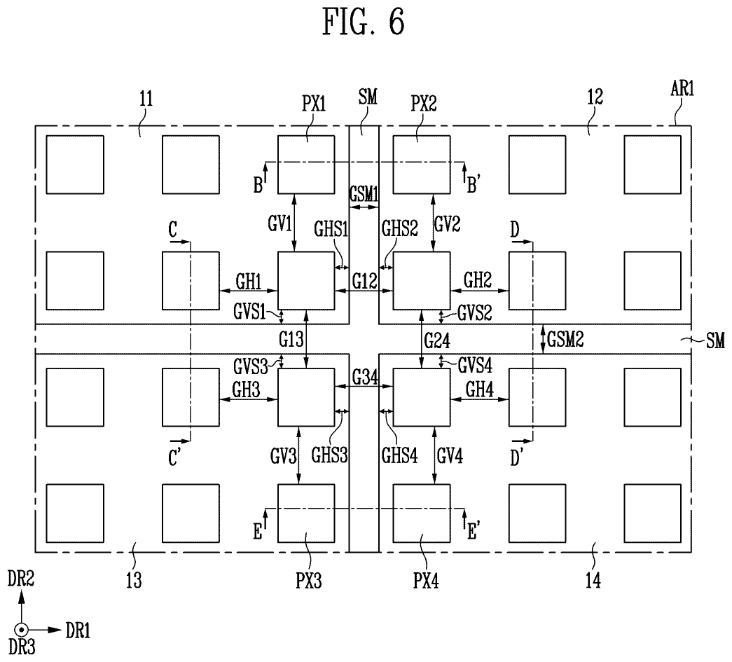

FIG. 6 is an enlarged plan view illustrating area AR1 of FIG. 5.

Referring to FIG. 6, the seam SM may have a planar shape of a cross or a plus sign in a center area of the tiled display device TLD where the first display device 11, the second display device 12, the third display device 13, and the fourth display device 14 are adjacent to each other.

The first display device 11 may include first pixels PX1 arranged in a matrix form in the first direction DR1 and the second direction DR2 to display an image. The second display device 12 may include second pixels PX2 arranged in a matrix form in the first direction DR1 and the second direction DR2 to display an image. The third display device 13 may include third pixels PX3 arranged in a matrix form in the first direction DR1 and the second direction DR2 to display an image. The fourth display device 14 may include fourth pixels PX4 arranged in a matrix form in the first direction DR1 and the second direction DR2 to display an image.

A minimum distance between first pixels PX1 adjacent to each other in the first direction DR1 may be defined as a first horizontal separation distance GH1. A minimum distance between second pixels PX2 adjacent to each other in the first direction DR1 may be defined as a second horizontal separation distance GH2. The first horizontal separation distance GH1 and the second horizontal separation distance GH2 may be substantially the same.

The seam SM may be disposed between a first pixel PX1 and a second pixel PX2 that are adjacent to each other in the first direction DR1. A minimum distance G12 between the first pixel PX1 and the second pixel PX2 that are adjacent to each other in the first direction DR1 may be the sum of a minimum distance GHS1 between the first pixel PX1 and the seam SM in the first direction DR1, a minimum distance GHS2 between the second pixel PX2 and the seam SM in the first direction DR1, and a width GSM1 of the seam SM in the first direction DR1.

The minimum distance G12 between the first pixel PX1 and the second pixel PX2 that are adjacent to each other in the first direction DR1, the first horizontal separation distance GH1, and the second horizontal separation distance GH2 may be substantially the same. To this end, the minimum distance GHS1 between the first pixel PX1 and the seam SM in the first direction DR1 may be smaller than the first horizontal separation distance GH1, and the minimum distance GHS2 between the second pixel PX2 and the seam SM in the first direction DR1 may be smaller than the second horizontal separation distance GH2. The width GSM1 of the seam SM in the first direction DR1 may be smaller than the first horizontal separation distance GH1 or the second horizontal separation distance GH2.

A minimum distance between third pixels PX3 adjacent to each other in the first direction DR1 may be defined as a third horizontal separation distance GH3, and a minimum distance between fourth pixels PX4 adjacent to each other in the first direction DR1 may be defined as a fourth horizontal separation distance GH4. The third horizontal separation distance GH3 and the fourth horizontal separation distance GH4 may be substantially the same.

The seam SM may be disposed between a third pixel PX3 and a fourth pixel PX4 that are adjacent to each other in the first direction DR1. A minimum distance G34 between the third pixel PX3 and the fourth pixel PX4 that are adjacent to each other in the first direction DR1 may be the sum of a minimum distance GHS3 between the third pixel PX3 and the seam SM in the first direction DR1, a minimum distance GHS4 between the fourth pixel PX4 and the seam SM in the first direction DR1, and the width GSM1 of the seam SM in the first direction DR1.

The minimum distance G34 between the third pixel PX3 and the fourth pixel PX4 that are adjacent to each other in the first direction DR1, the third horizontal separation distance GH3, and the fourth horizontal separation distance GH4 may be substantially the same. To this end, the minimum distance GHS3 between the third pixel PX3 and the seam SM in the first direction DR1 may be smaller than the third horizontal separation distance GH3, and the minimum distance GHS4 between the fourth pixel PX4 and the seam SM in the first direction DR1 may be smaller than the fourth horizontal separation distance GH4. The width GSM1 of the seam SM in the first direction DR1 may be smaller than the third horizontal separation distance GH3 or the fourth horizontal separation distance GH4.

A minimum distance between first pixels PX1 adjacent to each other in the second direction DR2 may be defined as a first vertical separation distance GV1. A minimum distance between third pixels PX3 adjacent to each other in the second direction DR2 may be defined as a third vertical separation distance GV3. The first vertical separation distance GV1 and the third vertical separation distance GV3 may be substantially the same.

The seam SM may be disposed between a first pixel PX1 and a third pixel PX3 that are adjacent to each other in the second direction DR2. A minimum distance G13 between the first pixel PX1 and the third pixel PX3 that are adjacent to each other in the second direction DR2 may be the sum of a minimum distance GVS1 between the first pixel PX1 and the seam SM in the second direction DR2, a minimum distance GVS3 between the third pixel PX3 and the seam SM in the second direction DR2, and a width GSM2 of the seam SM in the second direction DR2.

The minimum distance G13 between the first pixel PX1 and the third pixel PX3 that are adjacent to each other in the second direction DR2, the first vertical separation distance GV1, and the third vertical separation distance GV3 may be substantially the same. To this end, the minimum distance GVS1 between the first pixel PX1 and the seam SM in the second direction DR2 may be smaller than the first vertical separation distance GV1, and the minimum distance GVS3 between the third pixel PX3 and the seam SM in the second direction DR2 may be smaller than the third vertical separation distance GV3. The width GSM2 of the seam SM in the second direction DR2 may be smaller than the first vertical separation distance GV1 or the third vertical separation distance GV3.

A minimum distance between second pixels PX2 adjacent to each other in the second direction DR2 may be defined as a second vertical separation distance GV2. A minimum distance between fourth pixels PX4 adjacent to each other in the second direction DR2 may be defined as a fourth vertical separation distance GV4. The second vertical separation distance GV2 and the fourth vertical separation distance GV4 may be substantially the same.

The seam SM may be disposed between a second pixel PX2 and a fourth pixel PX4 that are adjacent to each other in the second direction DR2. A minimum distance G24 between the second pixel PX2 and the fourth pixel PX4 adjacent to each other in the second direction DR2 may be the sum of a minimum distance GVS2 between the second pixel PX2 and the seam SM in the second direction DR2, a minimum distance GVS4 between the fourth pixel PX4 and the seam SM in the second direction DR2, and the width GSM2 of the seam SM in the second direction DR2.

The minimum distance G24 between the second pixel PX2 and the fourth pixel PX4 that are adjacent to each other in the second direction DR2, the second vertical separation distance GV2, and the fourth vertical separation distance GV4 may be substantially the same. To this end, the minimum distance GVS2 between the second pixel PX2 and the seam SM in the second direction DR2 may be smaller than the second vertical separation distance GV2, and the minimum distance GVS4 between the fourth pixel PX4 and the seam SM in the second direction DR2 may be smaller than the fourth vertical separation distance GV4. The width GSM2 of the seam SM in the second direction DR2 may be smaller than the second vertical separation distance GV2 or the fourth vertical separation distance GV4.

As shown in FIG. 6, in order to prevent seams SM from being visually recognized between images displayed by the display devices 11, 12, 13, and 14, a minimum distance between pixels of adjacent display devices may be substantially equal to a minimum distance between pixels of each display device.

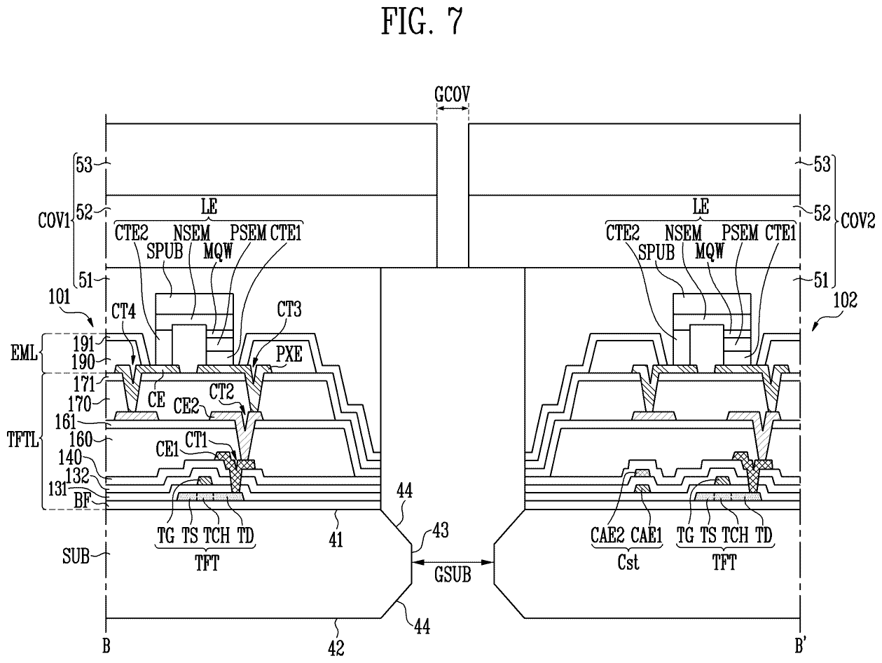

FIG. 7 is a schematic cross-sectional view illustrating an embodiment of the tiled display device taken along line B-B′ in FIG. 6.

Referring to FIG. 7, the first display device 11 (see FIG. 6) may include a first display panel 101 and a first front cover COV1. The second display device 12 (see FIG. 6) may include a second display panel 102 and a second front cover COV2.

Each of the first display panel 101 and the second display panel 102 may include the substrate SUB, the thin film transistor layer TFTL, and the light emitting element layer EML. The thin film transistor layer TFTL and the light emitting element layer EML have already been described in detail with reference to FIG. 4. In FIG. 7, descriptions that overlap with those of FIG. 4 will be omitted.

The substrate SUB may include a first surface 41 on which the thin film transistor layer TFTL is disposed, a second surface 42 facing the first surface 41, and a first side surface 43 disposed between the first surface 41 and the second surface 42. The first surface 41 may be a front surface or an upper surface of the substrate SUB, and the second surface 42 may be a bottom surface or a lower surface of the substrate SUB.

The substrate SUB may further include a chamfer surface 44 disposed between the first surface 41 and the first side surface 43 and between the second surface 42 and the first side surface 43. The thin film transistor layer TFTL and the light emitting element layer EML may not be disposed on the chamfer surface 44. Due to the chamfer surface 44, the substrate SUB of the first display device 11 and the substrate SUB of the second display device 12 may be prevented from colliding and being damaged.

The chamfer surface 44 may also be disposed between the first surface 41 and each of other side surfaces other than the first side surface 43 and between the second surface 42 and each of other side surfaces other than the first side surface 43. For example, in case that the first display device 11 and the second display device 12 have a rectangular planar shape as shown in FIG. 5, the chamfer surface 44 may be disposed between the first surface 41 and each of second, third, and fourth side surfaces and between the second surface 42 and each of the second, third, and fourth side surfaces.

The first front cover COV1 may be disposed on the chamfer surface 44 of the substrate SUB. For example, the first front cover COV1 may protrude further than the substrate SUB in the first direction DR1 and the second direction DR2. Therefore, a distance GSUB between the substrate SUB of the first display device 11 and the substrate SUB of the second display device 12 may be greater than a distance GCOV between the first front cover COV1 and the second front cover COV2 in the first direction DR1.

Each of the first front cover COV1 and the second front cover COV2 may include an adhesive member 51, a light transmittance adjustment layer 52 disposed on the adhesive member 51, an anti-glare layer 53 disposed on the light transmittance adjustment layer 52, and the like.

Below, components of the first front cover COV1 will be described according to an embodiment, but the description of the components may be applied to the second front cover COV2 as well.

The adhesive member 51 may be configured to attach the first front cover COV1 to the light emitting element layer EML of the first display panel 101. The adhesive member 51 may be a transparent adhesive member capable of transmitting light. For example, the adhesive member 51 may be an optically clear adhesive film (also referred to as an OCA film) or an optically clear resin (OCR).

The light transmittance adjustment layer 52 may be configured to reduce the transmittance of external light incident from outside. In another embodiment, the light transmittance adjustment layer 52 may be configured to reduce the transmittance of reflected light that is re-incident after the external light that has transmitted through the light transmittance adjustment layer 52 is reflected on the first display panel 101 and the second display panel 102. As the first front cover COV1 includes the light transmittance adjustment layer 52, the seam SM (see FIG. 6) may be prevented from being visually recognized from the outside. Accordingly, a seamless type tiled display device TLD (see FIG. 5) may be implemented.

The anti-glare layer 53 may be provided to reduce the phenomenon in which light reflected from a metal wiring and the like inside the display device 10 (see FIG. 1) is visually recognized from the outside. For example, the display device 10 may include a metal wiring in the thin film transistor layer TFTL or a metal wiring (for example, a pixel electrode PXE and the like) on the thin film transistor layer TFTL. As external light incident from the outside is reflected by the metal wiring and the like, the reflected light may be visually recognized from the outside. Excessive reflected light may act as a factor that reduces image visibility. Therefore, the anti-glare layer 53 may be designed to diffusely reflect external light and/or reflected light to prevent deterioration of image visibility. As the first front cover COV1 includes the anti-glare layer 53, the contrast ratio of the image displayed by the display device 10 (see FIG. 1) may be increased.

The light transmittance adjustment layer 52 may be implemented as, for example, a phase delay layer. The anti-glare layer 53 may be implemented as, for example, a polarizing plate. However, the disclosure is not limited thereto.

An embodiment of the tiled display device taken along lines C-C′, D-D′, and E-E′ in FIG. 6 and the embodiment of the tiled display device taken along line B-B′ described with reference to FIG. 7 may be similar or substantially the same.

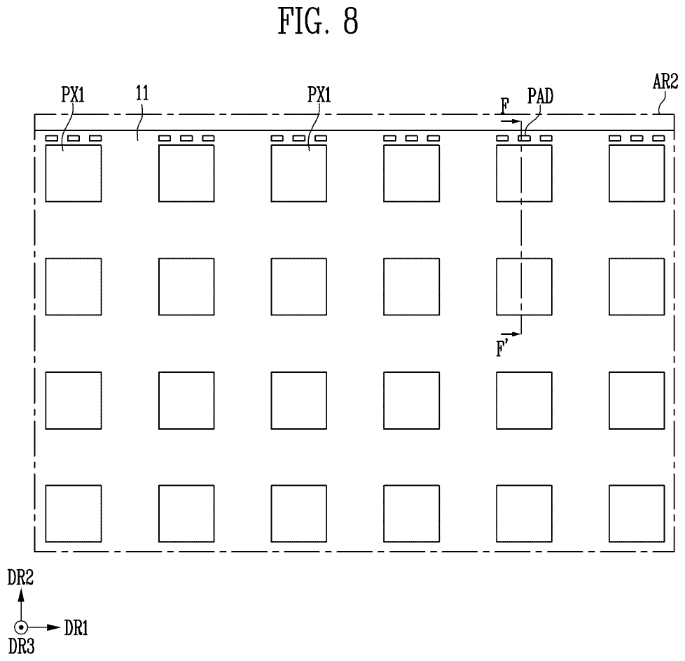

FIG. 8 is an enlarged plan view illustrating area AR2 of FIG. 5.

FIG. 8 schematically shows pads PAD and first pixels PX1 disposed on an upper side of the first display device 11.

Referring to FIG. 8, one or more pads PAD may be disposed on an upper edge of the first display device 11. In case that data lines (not shown) of the first display device 11 extend in the second direction DR2, the pads PAD may be disposed on an upper edge and/or a lower edge of the first display device 11. In another embodiment, in case that data lines of the first display device 11 extend in the first direction DR1, the pads PAD may be disposed on a left edge and/or a right edge of the first display device 11.

A pad PAD may be electrically connected to a data line. The pad PAD may be electrically connected to a side wiring (not shown).

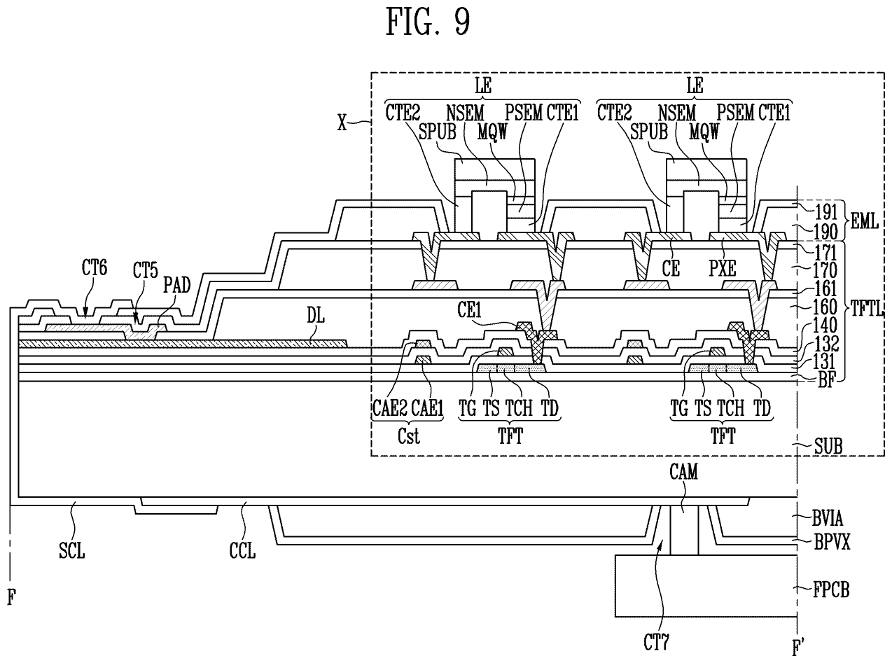

The side wiring may be disposed on a side surface of the substrate SUB (see FIG. 7), and may extend from the side surface to the lower surface (or the bottom surface). The side wiring may be connected to a connection wiring (not shown) on the lower surface of the substrate SUB. A detailed description of the side wiring and the connection wiring will be described in more detail with reference to FIG. 9 below.

FIG. 9 is a schematic cross-sectional view illustrating an embodiment of the tiled display device TLD (see FIG. 5) taken along line F-F′ in FIG. 8.

In FIG. 9, the same reference numerals are given to the same components as those shown in the cross-sectional view shown in FIG. 4. Descriptions that overlap with those of FIG. 4 will be omitted.

Referring to FIG. 9, the pad PAD may be disposed on the first insulating film 161. The pad PAD may be exposed without being covered by the bank insulating film 191. The pad PAD and the pixel electrode PXE may include a same material, or the pad PAD and the common electrode CE may include a same material. For example, the pad PAD may include a laminated structure of aluminum (Al) and titanium (Ti) (Ti/Al/Ti), a laminated structure of aluminum (Al) and ITO (ITO/AL/ITO), APC alloy, a laminated structure of APC alloy and ITO (ITO/APC/ITO), or the like. The pad PAD may include a metal material having high reflectivity.

The first data metal layer DTL1 may include a data line DL. The data line DL may be disposed on the interlayer insulating film 140. For example, the data line DL and the first connection electrode CE1 may be disposed on a same layer and may include a same material. The pad PAD may be electrically connected to the data line DL through a fifth contact hole CT5 penetrating the first insulating film 161. In an embodiment, a link wiring (not shown) may be further positioned between the pad PAD and the data line DL, and the pad PAD and the data line DL may not be directly connected, but may be electrically connected to each other through the link wiring.

A connecting wiring CCL may be disposed on the lower surface of the substrate SUB. The connecting wiring CCL may be a single layer or multiple layers made of at least one of molybdenum (Mo), aluminum (Al), chromium (Cr), gold (Au), titanium (Ti), nickel (Ni), neodymium (Nd), copper (Cu), and an alloy thereof.

A back planarization film BVIA may be arranged to cover a portion of the connecting wiring CCL. The back planarization film BVIA may be formed of an organic film such as an acryl resin, an epoxy resin, a phenolic resin, a polyamide resin, or a polyimide resin.

A back insulating film BPVX may be disposed on a lower surface of the back planarization film BVIA (for example, to cover the back planarization film BVIA). The back insulating film BPVX may include an inorganic film. For example, the inorganic film may be formed of a silicon nitride layer, a silicon oxynitride layer, a silicon oxide layer, a titanium oxide layer, or an aluminum oxide layer.

A side wiring SCL may extend from an edge of the lower surface of the substrate SUB to edges of the side and upper surfaces of the substrate SUB.

An end of the side wiring SCL may be electrically connected to the connecting wiring CCL. For example, an end of the side wiring SCL may be connected to side and lower surfaces of the connecting wiring CCL. Another end of the side wiring SCL may be electrically connected to the pad PAD. For example, another end of the side wiring SCL may be connected to the pad PAD through a sixth contact hole CT6 penetrating the bank insulating film 191.

The side wiring SCL may be disposed on the side surface of the substrate SUB, a side surface of the buffer film BF, a side surface of the first gate insulating film 131, a side surface of the second gate insulating film 132, a side surface of the interlayer insulating film 140, a side surface of the first insulating film 161, and a side surface of the second insulating film 171.

A flexible film FPCB may be disposed below the back insulating film BPVX (for example, in a direction toward the lower surface of the substrate SUB). The flexible film FPCB may be electrically connected to the connecting wiring CCL using a conductive adhesive member CAM.

The flexible film FPCB may be connected to the connecting wiring CCL through a seventh contact hole CT7.

The seventh contact hole CT7 may be a hole penetrating the back planarization film BVIA and the back insulating film BPVX, or may be a hole formed in an area from which the back planarization film BVIA and the back insulating film BPVX have been previously removed.

A data driving circuit (not shown) for supplying data voltages to data lines DL may be mounted on a surface of the flexible film FPCB. The flexible film FPCB may be implemented as, for example, a flexible printed circuit board, but the disclosure is not limited thereto. The data driving circuit may be implemented, for example, as a source driver integrated circuit (SDIC).

The conductive adhesive member CAM that electrically connects the flexible film FPCB and the connecting wiring CCL may be, for example, an anisotropic conductive film (ACF) or an anisotropic conductive paste (ACP). However, the disclosure is not limited thereto.

Referring to FIG. 9, the flexible film FPCB may be disposed on the lower surface of the substrate SUB and may be connected to the pad PAD through the connecting wiring CCL and the side wiring SCL. Accordingly, the pixels PX may be arranged up to an edge area of the display panel 100 (see FIG. 1), and a ratio of a display area where an image is displayed may be increased.

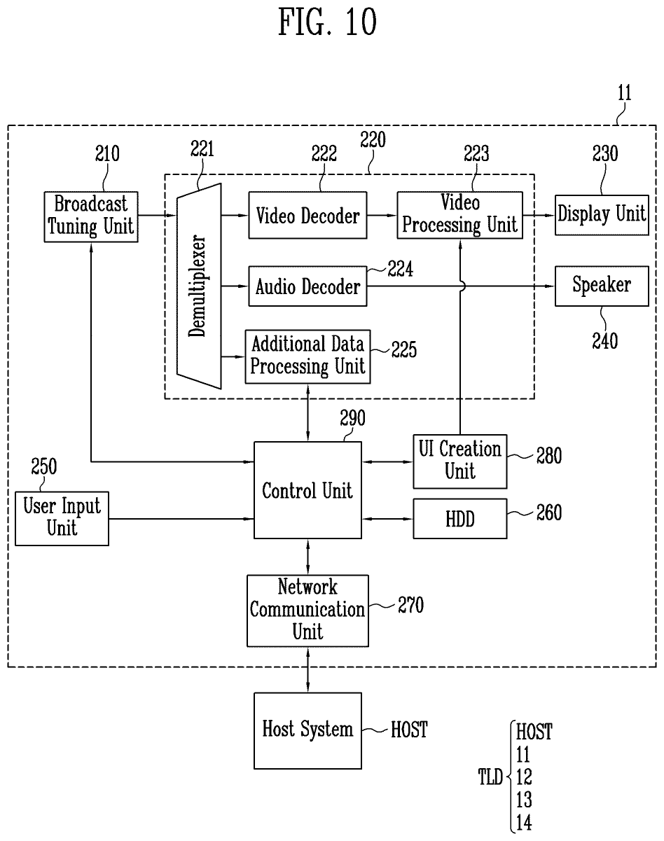

FIG. 10 is a block diagram illustrating the tiled display device TLD according to embodiments of the disclosure.

Referring to FIG. 10, the tiled display device TLD according to an embodiment may include a host system HOST and the display devices 11, 12, 13, and 14.

Although FIG. 10 shows an embodiment in which the host system HOST controls the first display device 11 for convenience of description, the host system HOST may also perform a function of controlling the display devices 11, 12, 13, and 14.

For example, the host system HOST may be implemented as a set-top box, an application processor (AP), or the like.

User commands may be entered into the host system HOST in a variety of formats. For example, the host system HOST may receive user commands through a user's touch input. In another embodiment, the host system HOST may receive user commands through an external input device (for example, keyboard input, button input on a remote controller, or the like).

The host system HOST may receive original video data corresponding to an original image from the outside. The host system HOST may divide the original video data by the number of display devices 11, 12, 13, and 14. For example, corresponding to the first display device 11, the second display device 12, the third display device 13, and the fourth display device 14, the host system HOST may divide the original video data into first video data corresponding to a first image, second video data corresponding to a second image, third video data corresponding to a third image, and fourth video data corresponding to a fourth image. The host system HOST may transmit the first video data to the first display device 11, transmit the second video data to the second display device 12, transmit the third video data to the third display device 13, and the fourth video data to the fourth display device 14.

The first display device 11 may display the first image according to the first video data, the second display device 12 may display the second image according to the second video data, the third display device 13 may display the third image according to the third video data, and the fourth display device 14 may display the fourth image according to the fourth video data. Accordingly, a user may watch the original image that is a combination of the first to fourth images displayed on the display devices 11, 12, 13, and 14.

Referring to FIG. 10, the first display device 11 may include a broadcast tuning unit 210, a signal processing unit 220, a display unit 230, a speaker 240, a user input unit 250, a hard disk drive (HDD) 260, a network communication unit 270, a UI (user interface) creation unit 280, a control unit 290, and the like.

The broadcast tuning unit 210 may tune a channel frequency under the control of the control unit 290 to receive a broadcast signal of a corresponding channel through an antenna. The broadcast tuning unit 210 may include a channel detection module, a radio frequency (RF) demodulation module, and the like.

The broadcast signal demodulated by the broadcast tuning unit 210 may be processed by the signal processing unit 220 and output to the display unit 230 and the speaker 240. The signal processing unit 220 may include a demultiplexer 221, a video decoder 222, a video processing unit 223, an audio decoder 224, an additional data processing unit 225, and the like.

The demultiplexer 221 may separate the demodulated broadcast signal into a video signal, an audio signal, and additional data. The separated video signal, audio signal, and additional data may be restored by the video decoder 222, the audio decoder 224, and the additional data processing unit 225, respectively. The video decoder 222, the audio decoder 224, and the additional data processing unit 225 may restore the separated video signal, audio signal, and additional data into a decoding format corresponding to an encoding format used when transmitting the broadcast signal, respectively.

The decoded video signal may be converted by the video processing unit 223 to meet output specifications of the display unit 230, such as vertical frequency, resolution, and screen ratio, and the decoded audio signal may be output to the speaker 240.

The display unit 230 may include the display panel 100 (see FIG. 1) on which an image is displayed and a panel driver that controls the operation of the display panel 100.

The user input unit 250 may receive a signal transmitted by the host system HOST. The user input unit 250 may be provided so that not only data regarding selection of a channel transmitted by the host system HOST and selection and manipulation of UI menus but also data regarding user's selection and input of commands related to communication with other display devices can be input.

The HDD 260 may store various software programs including an operating system (OS) program, recorded broadcast programs, videos, photos, and other data, and may be composed of a storage medium such as a hard disk or non-volatile memory. The HDD 260 may be referred to as a storage unit.

The network communication unit 270 may be provided for short-distance communication between the host system HOST and other display devices, and may be implemented as a communication module including an antenna pattern that can implement mobile communication, data communication, Bluetooth, RF, Ethernet, and the like. The network communication unit 270 may transmit and receive wireless signals with at least one of a base station, an external terminal, and a server through an antenna pattern to be described below on a mobile communication network built according to technical standards or communication methods for mobile communication (for example, GSM (Global System for Mobile communication), CDMA (Code Division Multi Access), CDMA2000 (Code Division Multi Access 2000), EV-DO (Enhanced Voice-Data Optimized or Enhanced Voice-Data Only), WCDMA (Wideband CDMA), HSDPA (High Speed Downlink Packet Access), HSUPA (High Speed Uplink Packet Access), LTE (Long Term Evolution), LTE-A (Long Term Evolution-Advanced), 5G, or the like.).

The network communication unit 270 may transmit and receive wireless signals through an antenna pattern to be described below in a communication network based on wireless Internet technologies. The wireless Internet technologies may include, for example, WLAN (Wireless LAN), Wi-Fi (Wireless-Fidelity), Wi-Fi Direct, DLNA (Digital Living Network Alliance), WiBro (Wireless Broadband), WiMAX (World Interoperability for Microwave Access), HSDPA (High Speed Downlink Packet Access), HSUPA (High Speed Uplink Packet Access), LTE (Long Term Evolution), LTE-A (Long Term Evolution-Advanced), or the like. The antenna pattern may transmit and receive data according to at least one wireless Internet technology, including Internet technologies not described above.

The UI creation unit 280 may be provided to generate a UI menu for communication between the host system HOST and other display devices, and may be implemented by algorithm code and an on screen display (OSD) integrated circuit (IC). The UI menu for communication between the host system HOST and other display devices may be a menu for specifying a digital TV with which communication is desired or selecting a desired function.

The control unit 290 may be provided to generally control the operation of the first display device 11 and control communication between the host system HOST and the second to fourth display devices 12, 13, and 14, and may be implemented as an MCU (Micro Controller Unit) in which a corresponding algorithm code for control is stored and the stored algorithm code is executed.

The control unit 290 may control operations such that corresponding control commands and data are transmitted to the host system HOST and the second to fourth display devices 12, 13, and 14 through the network communication unit 270 according to the input and selection of the user input unit 250. In case that control commands and data are input from the host system HOST and the second to fourth display devices 12, 13, and 14, the control unit 290 may perform operations according to the corresponding control commands.

Since a block diagram of the second display device 12, a block diagram of the third display device 13, and a block diagram of the fourth display device 14 may be substantially similar to the block diagram of the first display device 11 described with reference to FIG. 10, detailed descriptions thereof will be omitted.

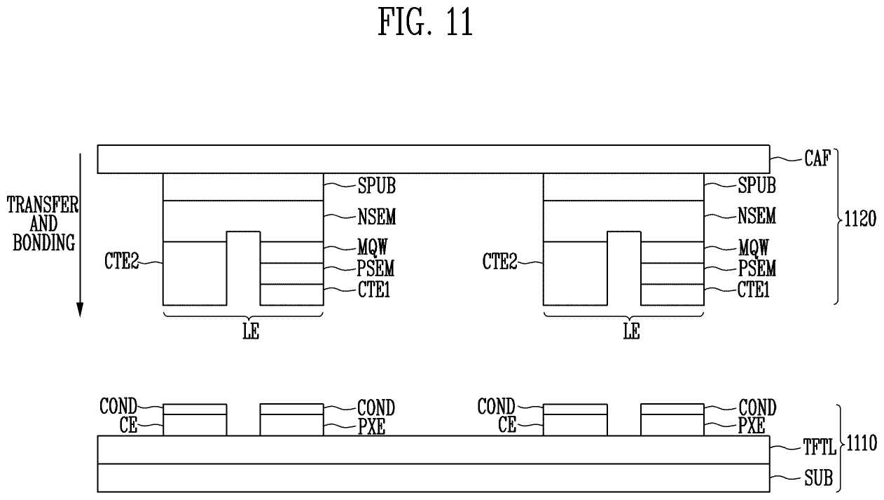

FIG. 11 is a schematic cross-sectional view illustrating a process of transferring a light emitting element LE.

Referring to FIG. 11, a thin film transistor substrate 1110 and a transfer substrate 1120 transferred to the thin film transistor substrate 1110 are schematically shown.

The thin film transistor substrate 1110 is simply shown as including the substrate SUB, the thin film transistor layer TFTL formed on the substrate SUB, and the common electrode CE and the pixel electrode PXE formed on the thin film transistor layer TFTL, but the disclosure is not limited thereto.

The transfer substrate 1120 may include multiple light emitting elements LE and a carrier substrate CAF configured to transfer the light emitting elements LE to the thin film transistor substrate 1110. A process of transferring the light emitting elements LE to the thin film transistor substrate 1110 may be referred to as a transfer process.

In order to transfer more light emitting elements LE onto the thin film transistor substrate 1110 in one transfer process, the transfer substrate 1120 may further include the carrier substrate CAF to which the light emitting elements LE are attached and detached. For example, the carrier substrate CAF may be implemented as a carrier film including an elastic polymer material such as silicon described above, but the disclosure is not limited thereto.

The carrier substrate CAF may be attached to the base substrate SPUB of the light emitting element LE. The carrier substrate CAF may be detached from the base substrate SPUB and removed at a time point after the transfer process is completed.

The light emitting element LE may be an inorganic light emitting element, and the light emitting element LE may be a micro light emitting diode (Micro LED). The light emitting elements LE may be transferred in a single transfer process using the carrier substrate CAF.

For electrical connection between the light emitting element LE and the common electrode CE or between the light emitting element LE and the pixel electrode PXE, a bonding process may be performed after the transfer process. Through the bonding process, electrical resistance between the light emitting element LE and the common electrode CE or between the light emitting element LE and the pixel electrode PXE may be reduced.

Referring to FIG. 11, the thin film transistor substrate 1110 may further include a conductive material COND disposed on the pixel electrode PXE and the common electrode CE.

The conductive material COND may be a component to increase adhesion between the light emitting element LE and the pixel electrode PXE or between the light emitting element LE and the common electrode CE. The conductive material COND may be a component for reducing electrical resistance between the light emitting element LE and the pixel electrode PXE or between the light emitting element LE and the common electrode CE.

The conductive material COND may be, for example, an anisotropic conductive film (ACF) or an anisotropic conductive paste (ACP). The conductive material COND may include, for example, a metallic conductive ball (not shown) having conductivity, or the like. The conductive material COND may become conductive by pressure or heat. However, the conductive material COND is not limited thereto.

Referring to FIG. 11, although the conductive material COND is shown as being disposed on both the pixel electrode PXE and the common electrode CE, the disclosure is not limited thereto, and in another embodiment, the conductive material COND may be disposed only on the pixel electrode PXE or only on the common electrode CE. In an embodiment, the thickness of the conductive material COND on the pixel electrode PXE and the thickness of the conductive material COND on the common electrode CE may be different.

Through the transfer process and the bonding process described above, the light emitting elements LE may be transferred onto the thin film transistor substrate 1110.

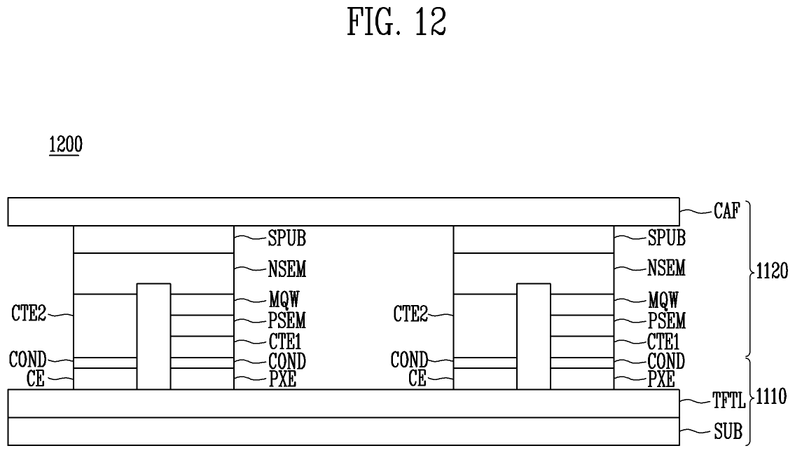

FIG. 12 is a schematic cross-sectional view illustrating an embodiment of a backplane substrate 1200 onto which the light emitting element EL is transferred.

Referring to FIG. 12, the backplane substrate 1200 may include the thin film transistor substrate 1110 and the transfer substrate 1120.

FIG. 12 schematically shows the backplane substrate 1200 in a state in which the light emitting elements LE (see FIG. 11) attached to the carrier substrate CAF are transferred onto the thin film transistor substrate 1110.

The backplane substrate 1200 may further include a mother substrate (not shown). After both the transfer process and the bonding process are performed, the mother substrate may be separated from the substrate SUB (for example, the lower surface of the substrate SUB) and removed. The mother substrate may be, for example, a rigid substrate made of glass or the like, or a flexible substrate made of a plastic or the like.

For example, the backplane substrate 1200 may include the substrate SUB for forming a display device 10 (see FIG. 1).

For example, the backplane substrate 1200 may include the substrate SUB on which two or more display devices 10 (see FIG. 1) are formed simultaneously. After the transfer process and the bonding process for the backplane substrate 1200 are completed, a scribing process for cutting the substrate SUB may be performed. Two or more display devices 10 may be separated from each other through the scribing process. A scribing line along which the substrate SUB is cut may be physically marked on the substrate SUB, but the disclosure is not limited thereto. The light emitting element LE (see FIG. 11) may not be transferred to the scribing line where the substrate SUB is cut. The light emitting element LE may not be bonded to the scribing line.

For example, the backplane substrate 1200 may include the substrate SUB for forming the display devices 11, 12, 13, and 14 (see FIG. 5) constituting the tiled display device TLD (see FIG. 5). On the substrate SUB, an area where multiple pads PAD (see FIG. 9) are disposed or an area where the side wiring SCL (see FIG. 9) is disposed may be an area where the light emitting element LE is not transferred or may be an area where the light emitting element LE is not bonded.

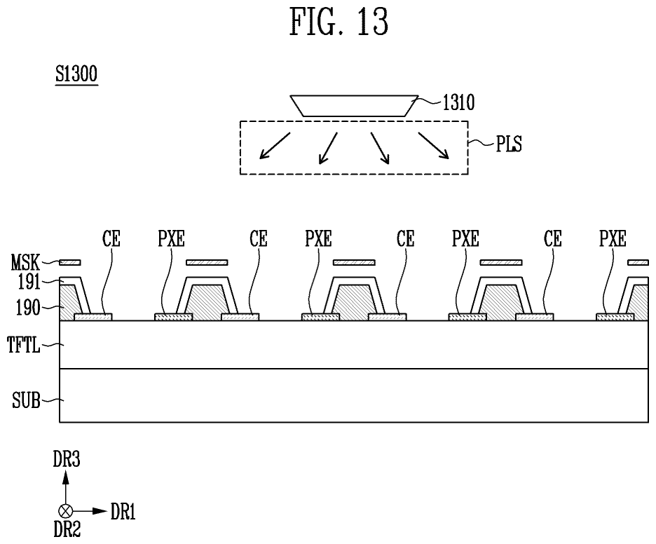

FIG. 13 is a schematic cross-sectional view illustrating an embodiment of a step of providing plasma onto a common electrode CE and a pixel electrode PXE.

Referring to FIG. 13, plasma PLS may be provided onto the common electrode CE and the pixel electrode PXE. The plasma PLS may be provided from an external plasma providing device 1310.

The plasma providing device 1310 may be positioned in a direction (for example, the third direction DR3) from the substrate SUB to provide the plasma PLS onto at least portions of the common electrode CE, the pixel electrode PXE, and the thin film transistor layer TFTL. The common electrode CE and the pixel electrode PXE provided with the plasma PLS may have hydrophilicity.

A mask MSK may be positioned on at least portions of the bank 190 and the bank insulating film 191. The plasma PLS may not be provided to areas blocked by the mask MSK on the thin film transistor layer TFTL. For example, the plasma PLS provided from a direction perpendicular (or substantially perpendicular) to the mask MSK may be blocked by the mask MSK and may not be provided to the bank 190 and/or the bank insulating film 191. The mask MSK may include openings configured to expose areas corresponding to the common electrode CE and the pixel electrode PXE.

In an embodiment, as the substrate SUB moves in a direction (for example, the first direction DR1), the plasma PLS may be provided from the plasma providing device 1310 onto the common electrode CE and the pixel electrode PXE. In another embodiment, as the plasma providing device 1310 moves in a direction (for example, the first direction DR1), the plasma PLS may be provided onto the common electrode CE and the pixel electrode PXE. In another embodiment, in a state in which both the substrate SUB and the plasma providing device 1310 are fixed, the plasma PLS may be provided from the plasma providing device 1310 onto the common electrode CE and the pixel electrode PXE. However, the disclosure is not limited to the above description.

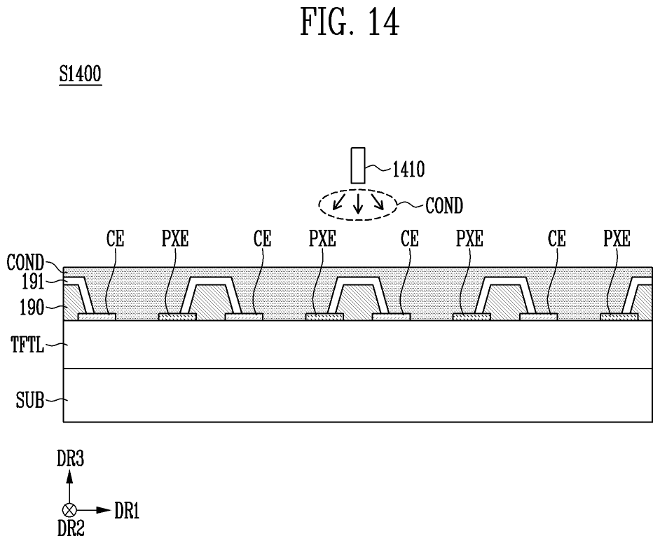

FIG. 14 is a schematic cross-sectional view illustrating an embodiment of a step of providing a conductive material on the common electrode CE and the pixel electrode PXE.

Referring to FIG. 14, the conductive material COND may be provided on the common electrode CE and the pixel electrode PXE. The conductive material COND may be provided from a conductive material providing device 1410. For example, the conductive material COND may be discharged from a nozzle of the conductive material providing device 1410 and deposited on the common electrode CE and the pixel electrode PXE. The conductive material COND may be further deposited on at least some areas of the bank 190 and the bank insulating film 191. For example, the conductive material COND may completely cover the common electrode CE, the pixel electrode PXE, and the bank insulating film 191.

In an embodiment, as the substrate SUB moves in a direction (for example, the first direction DR1), the conductive material COND may be provided from the conductive material providing device 1410. In another embodiment, as the conductive material providing device 1410 moves in a direction (for example, the first direction DR1), the conductive material COND may be provided. In another embodiment, in a state in which both the substrate SUB and the conductive material providing device 1410 are fixed, the conductive material COND may be provided from the conductive material providing device 1410. However, the disclosure is not limited to the above description.

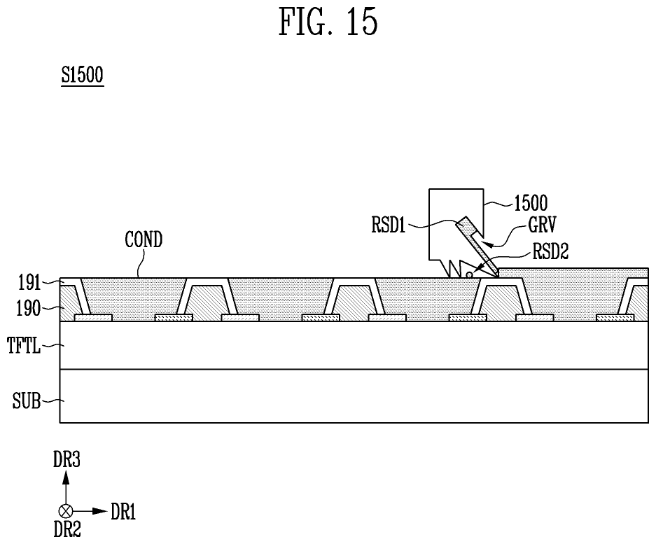

FIG. 15 is a schematic cross-sectional view illustrating an embodiment of a step of removing the conductive material COND using a cleaner 1500.

Referring to FIG. 15, the cleaner 1500 may remove at least a portion of the conductive material COND. The cleaner 1500 may be configured to remove the conductive material COND from at least some areas on the bank insulating film 191. At least a portion of an upper surface of the bank insulating film 191 may be exposed in the areas where the conductive material COND has been removed.

The cleaner 1500 may include a groove GRV. A first residue RSD1 corresponding to the removed conductive material COND may be accommodated in the groove GRV.

The cleaner 1500 may planarize an upper surface of the conductive material COND from which the first residue RSD1 has been removed by removing a second residue RSD2 corresponding to an uneven surface.

In an embodiment, as the substrate SUB moves in a direction (for example, a direction opposite to the first direction DR1), the conductive material COND may be removed by the cleaner 1500. In another embodiment, as the cleaner 1500 moves in a direction (for example, the first direction DR1), the conductive material COND may be removed. However, the disclosure is not limited to the above description.

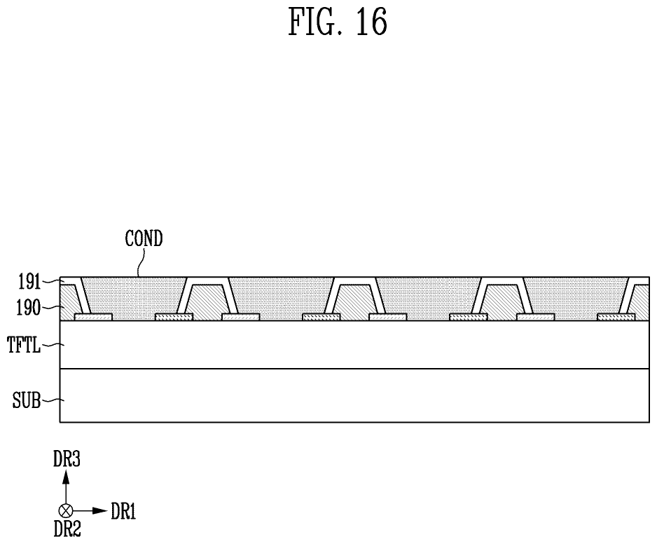

FIG. 16 is a schematic cross-sectional view illustrating an embodiment in a state in which the conductive material COND is removed by the cleaner.

Referring to FIG. 16, the upper surface of the conductive material COND may be entirely planarized by the cleaner 1500 (see FIG. 15). For example, the upper surface of the conductive material COND may be configured to be entirely planarized along with the upper surface of the bank insulating film 191.

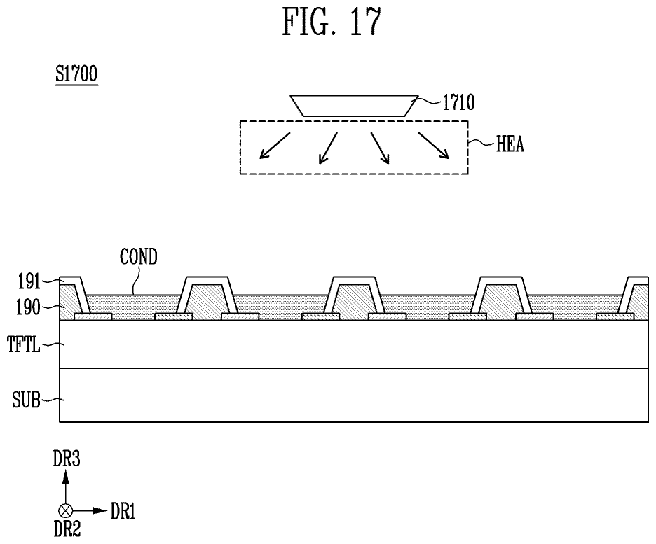

FIG. 17 is a schematic cross-sectional view illustrating an embodiment of a step of removing the conductive material COND using a heater 1710.

Referring to FIG. 17, the heater 1710 may provide heat HEA. The conductive material COND may be evaporated by the heat HEA. As a portion of the conductive material COND is evaporated and removed by the heater 1710, the conductive material COND may have an overall planarized upper surface. In an embodiment, in areas between banks 190, the conductive material COND may be removed at a uniform rate throughout.

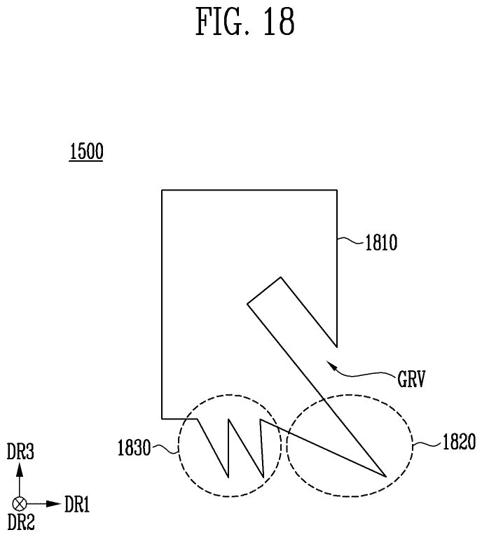

FIG. 18 is a schematic cross-sectional view of a cleaner 1500 according to an embodiment.

Referring to FIG. 18, the cleaner 1500 may include a body portion 1810, a first inclined portion 1820, and a second inclined portion 1830. According to an embodiment, the body portion 1810, the first inclined portion 1820, and the second inclined portion 1830 may be composed of one component. In another embodiment, the body portion 1810, the first inclined portion 1820, and the second inclined portion 1830 may be composed of separate components. However, the disclosure is not limited to the above description.

The body portion 1810 may include the groove GRV formed to be recessed toward the inside. A depth of the groove GRV may be designed in consideration of the amount of conductive material removed by the cleaner 1500.

The first inclined portion 1820 may be configured to shave the conductive material and guide the shaved conductive material into the groove GRV. For example, the first inclined portion 1820 may have a wedge shape in a cross-sectional view. The first inclined portion 1820 may be connected to the body portion 1810. The first inclined portion 1820 may include an inclined surface connected to the groove GRV. For example, a direction from the first inclined portion 1820 to the groove GRV may correspond to a direction between a direction opposite to the first direction DR1 and the third direction DR3.

The first inclined portion 1820 may have hydrophobicity. According to an embodiment, the phenomenon of the conductive material sticking to the first inclined portion 1820 may be alleviated.

The first inclined portion 1820 may be made of a material having relatively greater elasticity than the second inclined portion 1830. For example, the first inclined portion 1820 may include a material such as rubber or silicon. However, the disclosure is not limited thereto.

The second inclined portion 1830 may be connected to the body portion 1810. The second inclined portion 1830 may be located in a direction opposite to the first direction DR1 from the first inclined portion 1820.

The second inclined portion 1830 may be configured to planarize the upper surface of the conductive material. In an embodiment, the second inclined portion 1830 may have a wedge shape in a cross-sectional view. For example, the second inclined portion 1830 may perform the function of planarizing the conductive material having an uneven upper surface.

The second inclined portion 1830 may have hydrophobicity. According to an embodiment, the phenomenon of the conductive material sticking to the second inclined portion 1820 may be alleviated.

The second inclined portion 1830 may be made of a material having relatively lower elasticity than the first inclined portion 1820. For example, the second inclined portion 1830 may include a material such as rubber or silicon. For example, an elastic modulus of the material constituting the first inclined portion 1820 may be relatively small, and an elastic modulus of the material constituting the second inclined portion 1830 may be relatively large. In other words, the first inclined portion 1820 may be made of a relatively soft material, and the second inclined portion 1830 may be made of a relatively hard material. As a result, the first inclined portion 1820, which has a relatively small elastic modulus, may be suitable for shaving the conductive material and guiding the shaved conductive material into the groove GRV. As a result, the second inclined portion 1830, which has a relatively large elastic modulus, may be more suitable for planarizing the upper surface of the conductive material.

The second inclined portion 1830 may include one or more wedge shapes. Referring to FIG. 18, the second inclined portion 1830 may include two or more wedge shapes. According to an embodiment of the second inclined portion 1830 including multiple wedge shapes, the function of planarizing the conductive material may be performed more effectively.

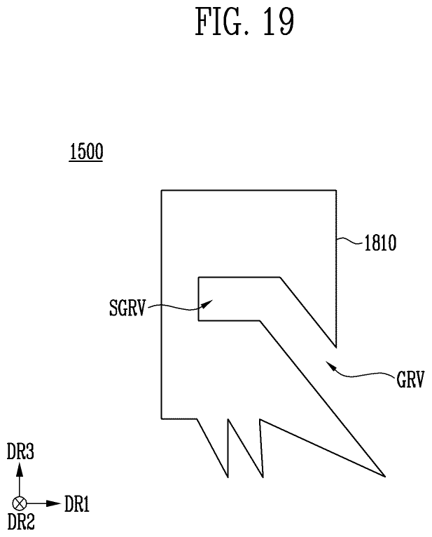

FIG. 19 is a schematic cross-sectional view of a cleaner 1500 according to another embodiment.

Referring to FIG. 19, the cleaner 1500 may include the groove GRV. The groove GRV may include a sub-groove SGRV. The remaining components may be the same as or similar to the cleaner 1500 described with reference to FIG. 18.

The sub-groove SGRV may be formed by further recessing the body portion 1810 from the groove GRV in a direction (for example, a direction opposite to the first direction DR1). According to an embodiment, the conductive material may be accommodated more effectively by increasing the volume of the groove GRV.

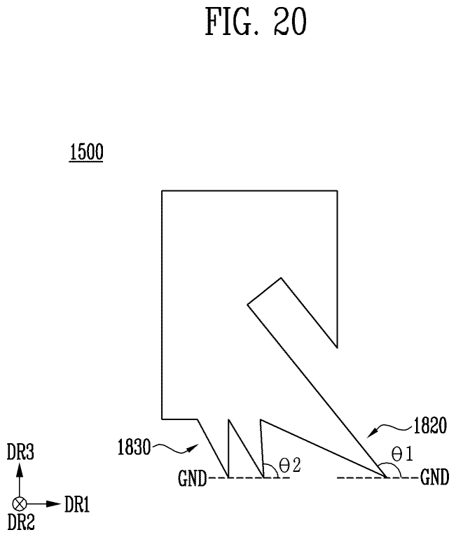

FIG. 20 is a schematic cross-sectional view illustrating angles formed by a first inclined portion 1820 and a second inclined portion 1830 with the ground GND in the cleaner 1500 according to embodiments of the disclosure.

Referring to FIG. 20, an angle formed by the first inclined portion 1820 with the ground GND may be a first angle θ1. An angle formed by the second inclined portion 1830 with the ground GND may be a second angle θ2. For example, an angle formed by an inclined surface of the first inclined portion 1820 with the ground GND may be the first angle θ1. For example, an angle formed by an inclined surface of the second inclined portion 1830 with the ground GND may be the second angle θ2.

The first angle θ1 may be greater than the second angle θ2. According to an embodiment, the first angle θ1 may be an obtuse angle greater than 90°. According to an embodiment, both the first angle θ1 and the second angle θ2 may be obtuse angles greater than 90°.

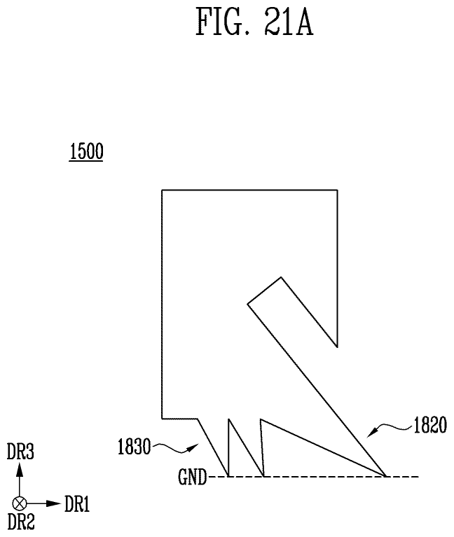

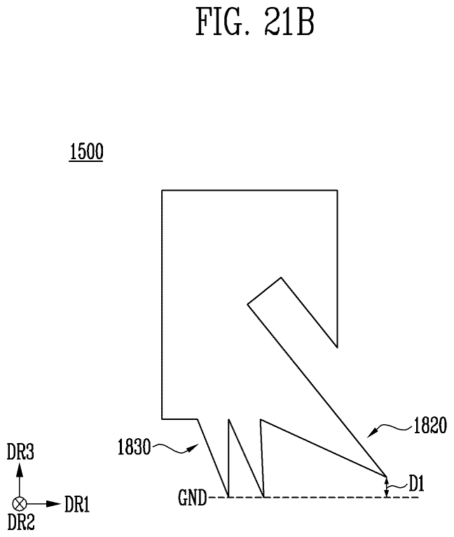

FIGS. 21A and 21B are schematic cross-sectional views illustrating distances between the first inclined portion 1820 and the second inclined portion 1830 and the ground according to embodiments of the disclosure.

Referring to FIG. 21A, in an embodiment, a distance between the first inclined portion 1820 and the ground GND may be the equal to (or substantially equal to) a distance between the second inclined portion 1830 and the ground GND. For example, in case that the second inclined portion 1830 contacts the ground GND, the distance between the first inclined portion 1820 and the ground GND may be 0 (or substantially 0).

Referring to FIG. 21B, in another embodiment, the distance between the second inclined portion 1830 and the ground GND may be less than the distance between the first inclined portion 1820 and the ground GND. For example, in case that the second inclined portion 1830 contacts the ground GND, the distance between the first inclined portion 1820 and the ground GND may be a first distance D1 greater than 0.

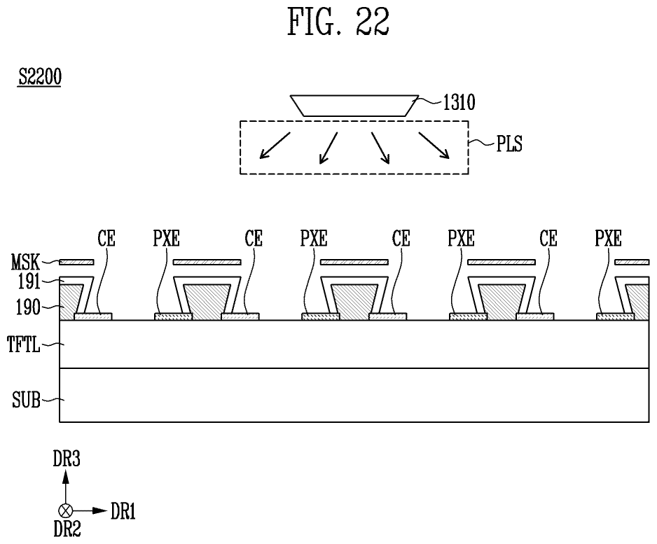

FIG. 22 is a schematic cross-sectional view illustrating another embodiment of the step of providing the plasma PLS onto the common electrode CE and the pixel electrode PXE.

Compared to FIG. 13, in an embodiment of FIG. 22, the bank 190 may have an inverted tapered shape in a cross-sectional view. The bank insulating film 191 may surround side and upper surfaces of the bank 190 having an inverted tapered shape. The remaining components may be configured the same as or similar to the components shown in FIG. 13.

The Plasma PLS may be provided onto the common electrode CE and the pixel electrode PXE in an area surrounded by the bank 190.

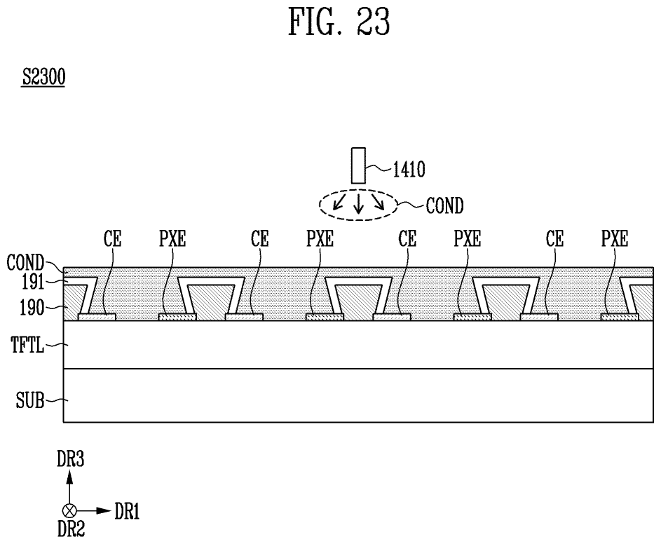

FIG. 23 is a schematic cross-sectional view illustrating another embodiment of the step of providing the conductive material on the common electrode CE and the pixel electrode PXE.

Compared to FIG. 14, in the embodiment of FIG. 23, the bank 190 may have an inverted tapered shape in a cross-sectional view. In an embodiment of FIG. 23, the bank 190 may have an inverted tapered shape in a cross-sectional view. The conductive material COND may be filled in an area surrounded by the side of the bank 190 having an inverted tapered shape. The conductive material COND may be located on the bank 190 having an inverted tapered shape. The remaining components may be configured the same as or similar to the components shown in FIG. 14.

The conductive material COND may be provided on the area surrounded by the bank 190 and the bank insulating film 191.

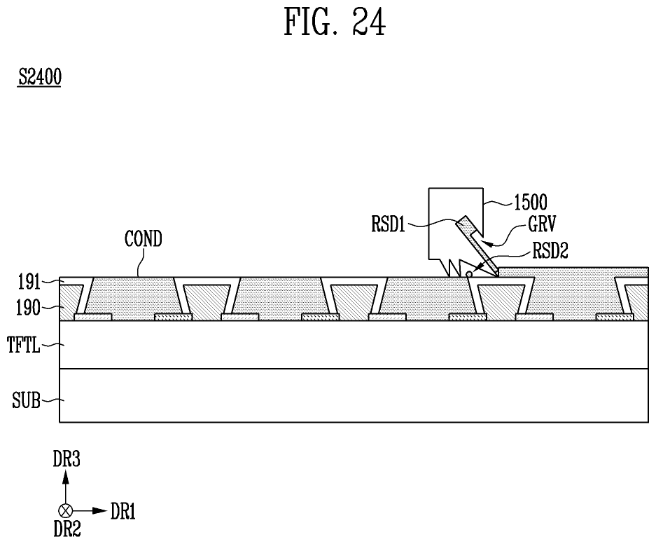

FIG. 24 is a schematic cross-sectional view illustrating another embodiment of the step of removing the conductive material COND using the cleaner 1500.

Compared to FIG. 15, in an embodiment of FIG. 24, the bank 190 may have an inverted tapered shape in a cross-sectional view. The cleaner 1500 may remove at least a portion of the conductive material COND on the bank 190 having an inverted tapered shape. The remaining components may be configured the same as or similar to the components shown in FIG. 15.

At least a portion of the conductive material COND may be removed on the bank 190 having an inverted tapered shape. The upper surface of the conductive material COND may be planarized by the cleaner 1500.

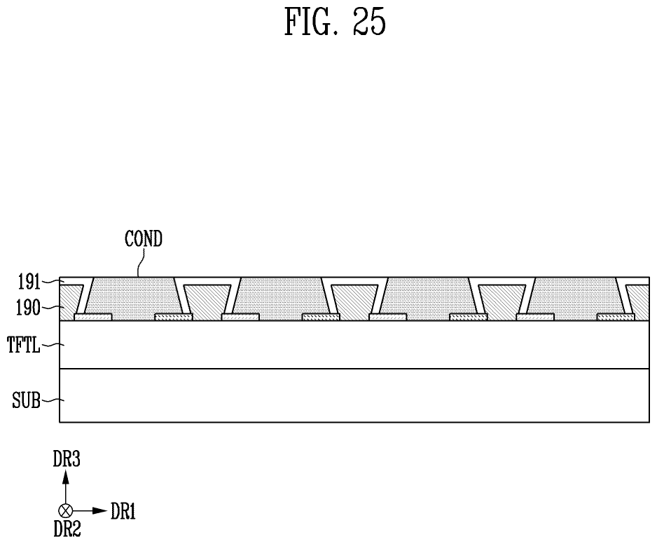

FIG. 25 is a schematic cross-sectional view illustrating another embodiment in the state in which the conductive material COND is removed by the cleaner.

Compared to FIG. 16, in an embodiment of FIG. 25, the bank 190 may have an inverted tapered shape in a cross-sectional view. An area surrounded by the bank 190 having an inverted tapered shape may be filled with the conductive material COND.

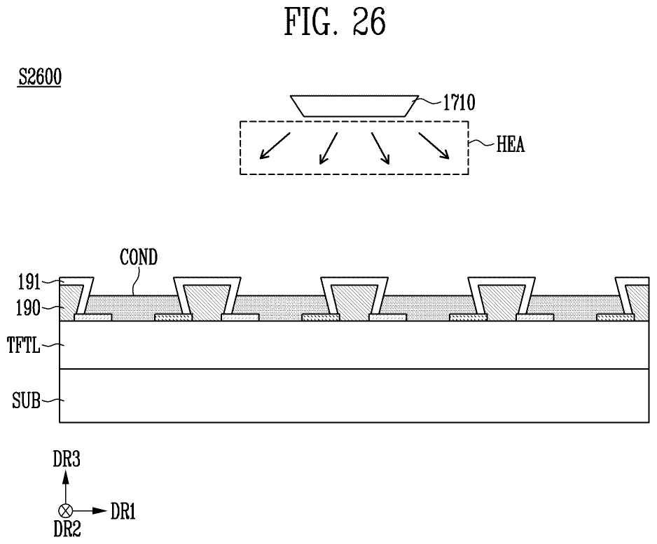

FIG. 26 is a schematic cross-sectional view illustrating another embodiment of the step of removing the conductive material COND using the heater 1710.

Compared to FIG. 17, in an embodiment of FIG. 26, the bank 190 may have an inverted tapered shape in a cross-sectional view. In an area surrounded by the bank 190 having an inverted tapered shape, at least a portion of the conductive material COND may be removed by evaporation.

Compared to the embodiment of FIG. 17, in the embodiment of FIG. 26, the conductive material COND may be confined more effectively in the embodiment where the conductive material COND is surrounded by the bank 190 having an inverted tapered shape.

According to the cleaner, the display panel manufactured using the same, and the method of manufacturing the same according to embodiments of the disclosure, the upper surface of the conductive material used in the bonding process may be planarized.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A cleaner comprising:
a body portion including a groove recessed toward inside of the body portion;
a first inclined portion extending from the body portion, connected to the groove, and forming a first inclined angle that is an obtuse angle with a ground; and
a second inclined portion connected to the first inclined portion and forming a second inclined angle with the ground, the second inclined angle being smaller than the first inclined angle.

2. The cleaner of claim 1, wherein an elastic modulus of the first inclined portion is smaller than an elastic modulus of the second inclined portion.

3. The cleaner of claim 2, wherein
the first inclined portion is composed of one of rubber and silicone,
the second inclined portion is composed of one of rubber and silicone, and
an elastic modulus of a material constituting the first inclined portion is smaller than an elastic modulus of a material constituting the second inclined portion.

4. The cleaner of claim 1, wherein
the first inclined portion includes a wedge shape forming the first inclined angle with the ground, and
the second inclined portion includes a wedge shape forming the second inclined angle with the ground.

5. The cleaner of claim 1, wherein
the body portion further includes a sub-groove further recessed to extend in a horizontal direction from the groove, and
the second inclined portion is located in the horizontal direction from the first inclined portion.

6. The cleaner of claim 1, wherein a distance between the first inclined portion and the ground is equal to a distance between the second inclined portion and the ground.

7. The cleaner of claim 1, wherein a distance between the first inclined portion and the ground is greater than a distance between the second inclined portion and the ground.

8. A display panel comprising:
a thin film transistor layer located on a substrate and in which a pixel circuit including at least one transistor is disposed;
a pixel electrode located on the thin film transistor layer and connected to the pixel circuit;
a common electrode located on the thin film transistor layer and to which a first power source voltage is applied;
a bank located on at least a portion of the common electrode and at least a portion of the pixel electrode;
a conductive material located on the common electrode and the pixel electrode in an area surrounded by the bank; and
a light emitting element connected to the common electrode and the pixel electrode in the area surrounded by the bank with the conductive material interposed between the light emitting element and the common electrode and between the light emitting element and the pixel electrode,
wherein the conductive material on the bank is removed by a first inclined portion of a cleaner and planarized by a second inclined portion of the cleaner.

9. The display panel of claim 8, wherein
a first residue of the conductive material removed by the first inclined portion is accommodated in a groove of the cleaner, and
the groove of the cleaner is connected to the first inclined portion of the cleaner.

10. The display panel of claim 9, wherein a second residue corresponding to an upper surface of the conductive material from which the first residue has been removed is planarized by the second inclined portion.

11. The display panel of claim 8, wherein the bank has a tapered shape in a cross-sectional view.

12. The display panel of claim 8, wherein the bank has an inverted tapered shape in a cross-sectional view.

13. A method of manufacturing a display panel comprising:
providing plasma onto a common electrode and a pixel electrode located in an area surrounded by a bank on a substrate by a plasma providing device;
providing a conductive material on the common electrode, the pixel electrode, and the bank by a conductive material providing device;
removing and accommodating the conductive material on the bank by a cleaner, and planarizing an upper surface of the conductive material by the cleaner; and
evaporating at least a portion of the conductive material in the area surrounded by the bank by a heater.

14. The method of claim 13, wherein in the providing of the plasma onto the common electrode and the pixel electrode located in the area surrounded by the bank on the substrate by the plasma providing device,
a mask for blocking the plasma is positioned on the bank, and
an opening of the mask is positioned corresponding to the area surrounded by the bank.

15. The method of claim 13, wherein the removing and accommodating of the conductive material on the bank by the cleaner, and the planarizing of the upper surface of the conductive material by the cleaner includes:
shaving and removing the conductive material by a first inclined portion of the cleaner;
accommodating a first residue corresponding to the conductive material shaved by the first inclined portion in a groove of the cleaner; and
planarizing the upper surface of the conductive material from which the first residue has been removed by a second inclined portion of the cleaner.

16. The method of claim 15, wherein
the second inclined portion is located in a horizontal direction from the first inclined portion, and
in the accommodating of the first residue corresponding to the conductive material shaved by the first inclined portion in the groove of the cleaner, the first residue is further accommodated in a sub-groove extending in the horizontal direction from the groove.

17. The method of claim 15, wherein
a first inclined angle formed by the first inclined portion with a ground is an obtuse angle, and
the first inclined angle is greater than a second inclined angle formed by the second inclined portion with the ground.

18. The method of claim 17, wherein a distance between the first inclined portion and the ground is equal to a distance between the second inclined portion and the ground.

19. The method of claim 13, wherein in the evaporating of the at least a portion of the conductive material in the area surrounded by the bank by the heater, the bank has a tapered shape in a cross-sectional view.

20. The method of claim 13, wherein in the evaporating of the at least a portion of the conductive material in the area surrounded by the bank by the heater, the bank has an inverted tapered shape in a cross-sectional view.
